(19) United States
(12) Patent Application Publication
(10) Pub. No.: US 2026/0003931 A1
(43) Pub. Date: Jan. 1, 2026

(54) SIGNAL PROCESSING APPARATUS AND METHOD

(71) Applicant: NEC Corporation, Tokyo (JP)

(72) Inventor: Atsufumi SHIBAYAMA, Tokyo (JP)

(73) Assignee: NEC Corporation, Tokyo (JP)

(21) Appl. No.: 19/245,591

(22) Filed: Jun. 23, 2025

(30) Foreign Application Priority Data
Jun. 27, 2024 (JP) 2024-103795

(51) Int. Cl. G06F 17/14; G06F 5/01; H03K 19/20

(52) U.S. Cl. CPC G06F 17/142; G06F 5/01; H03K 19/20

(57) ABSTRACT

A signal processing apparatus includes a storage processing part to perform processing on data represented in a second representation format, wherein the second representation format, while for a non-negative value identical to two's complement representation, for a negative value, has a representation format where (D−N−1) bits of the data of D-bits in the two's complement representation are bit-wise inverted, the (D−N−1) bits located between MSB and N consecutive lower bits including LSB, the storage processing part including a normalization circuit with a maximum exponent calculation circuit and a shift circuit to normalize a plurality of pieces of data represented in the second representation format for each block.

### REFERENCE TO RELATED APPLICATION

The present disclosure is based upon and claims the benefit of the priority of Japanese patent application No. 2024-103795 filed on Jun. 27, 2024, the disclosure of which is incorporated herein in its entirety by reference thereto.

### FIELD

The present disclosure relate s to a signal processing apparatus and method.

### BACKGROUND

Fast Fourier transform (FFT) processing is one of important processing techniques in digital signal processing. For example, frequency domain equalization (FDE) is known as a technique that compensates for waveform distortion during signal transmission in wireless or wired communication. In the frequency domain equalization (FDE), time domain signal data is first transformed to frequency domain data by FFT. Next, a filtering process for equalization is performed in frequency domain. Then, the data filtered in frequency domain is transformed back to time domain signal data by inverse fast Fourier transform (IFFT). By the above process, a waveform distortion of an original time domain signal is compensated. When FFT and IFFT are not distinguished, they may be denoted by “FFT/IFFT.”

In general, a “butterfly operation” is used in FFT/IFFT processing. For example, Reference Literature 1 discloses an FFT apparatus using a butterfly operation. Reference Literature 1 also discloses “twiddle factor multiplication” (described later), i.e., multiplication using a twiddle coefficient or twiddle factor. For instance, Reference Literature 4 discloses a Cooley-Tukey butterfly operation as an efficient FFT/IFFT processing method. The Cooley-Tukey FFT/IFFT with a large number of points, however, requires a complex circuit. Hence, FFT/IFFT processing is decomposed into two smaller FFTs/IFFTs by using a Prime Factor method described in Reference Literature 5, for example.

FIG. 21 illustrates data flow 500 of a 64-point FFT decomposed into a two-stage radix-8 butterfly process by using the Prime Factor method. The data flow 500 includes a data reordering processing part 501, radix-8 butterfly operations performed a total of sixteen times by butterfly operation processing parts 502 and 503, and a twiddle factor multiplication processing part 504 that multiplies a twiddle factor {W^{k}} (W=exp(−2πj/N), j²=−1). In FIG. 21, twiddle factors are (W⁰, W¹, . . . , W⁷), (W⁰, W⁷, . . . , W⁴⁹)). In the data flow 500 illustrated in FIG. 21, input time-domain data x(n) (n=0, 1, . . . , 63) is transformed to frequency-domain signals X(k) (k=0, 1, . . . , 63) by the FFT processing. In FIG. 21, a part of the data flow is omitted. Even when performing IFFT processing, a basic structure of the data flow is the same as the data flow 500 illustrated in FIG. 21. Input frequency-domain signals X(k) (k=0, 1, . . . , 63) are transformed (IFFT) by the processing of the data flow 500 to time-domain data x(n) (n=0, 1, . . . , 63) for output.

In a case where the number of FFT points is large, if the data flow 500 illustrated in FIG. 21 all is to be implemented by a circuit, the circuit would be of an enormous scale. Therefore, such an approach is generally adopted that the entirety of the FFT processing is implemented by repeatedly utilizing a circuit that implements a partial processing of a data flow according to a processing performance needed, in the case where the number of FFT points is large.

For example, in the data flow in FIG. 21, if an FFT apparatus that performs FFT processing on eight pieces of data in parallel (referred to as “in 8-data parallel” for short) is configured as a physical circuit, 64-point FFT processing can be implemented by repeating the processing eight times in total. Processing repeated eight times is performed sequentially, each corresponding to each of partial data flows 505a to 505h performed on eight pieces of data. More specifically, the processing is performed as follows:
at the first time, the processing corresponding to the partial data flow 505a is performed,
at the second time, the processing corresponding to the partial data flow 505b is performed,
at the third time, the processing corresponding to the partial data flow 505c (not shown in the drawing) is performed.
   Similarly, each of the processing up to the eighth partial data flow 505h is sequentially performed thereafter. The 64-point FFT processing is realized by the processing described above.

In a butterfly operation, a plurality of items of data arranged in a sequential order are read in an order according to a predetermined rule and processed. Therefore, the butterfly operation needs reordering of a plurality of items of data, for which a RAM (Random Access Memory) circuit(s) is/are mainly used. For example, Reference Literature 2 describes an FFT apparatus that performs reordering of a plurality of items of data using a RAM circuit(s) for a butterfly operation.

### [PTL 1]

International Publication Number WO2019/131754 (Page 7, FIG. 1)

### SUMMARY

A two's complement representation is widely used as a representation scheme of signal data using binary number's digits in digital signal processing. In the two's complement representation, an addition/subtraction processing circuit can be realized with a small circuit scale because the same circuit can be used to perform both addition and subtraction.

On the other hand, a value per bit greatly differs between a small positive value and a small negative value in a vicinity of a value zero in the two's complement representation. As a result, if a signal taking a value which frequently changes between positive and negative in a vicinity of zero is to be represented by a two's complement, a bit-wise operation rate (toggle rate) would become large. Dynamic power dissipation (dynamic power dissipation) P of a digital signal processing circuit realized by a CMOS (Complementary Metal Oxide Semiconductor) circuit can be expressed by the following Equation (1):

$$P = ( 1 / 2 ) * a * C * V 2 * f \qquad ( 1 )$$

where
a: circuit operation rate (percentage-activity),
C: load capacity,
V: voltage, and
f: operating frequency.

A circuit operation rate (percentage-activity) is a ratio between an estimated value of the number of switching and the number of clock cycles during a certain period of time.

Since a bit-wise operation rate (toggle rate) of signal data determines the percentage-activity a, reduction of the bit-wise operation rate is effective for reduction of power dissipation (power dissipation). Signal data in signal processing for communication often changes between positive and negative in the vicinity of a value zero.

In a fast Fourier transform (FFT) which is one of important processes in digital signal processing, internal data often takes a small value near a value zero. When the two's complement representation is used in these processes, the bit-wise operation rate may become large, resulting in an increase of power dissipation.

To address this, there is a sign magnitude representation, as a representation scheme of digital data having a small bit-wise operation rate in a vicinity of the value zero.

As an example of the two's complement representation and the sign magnitude representation, FIG. 22 shows binary representations of signal values of +15 to −16 in 5-bit signal data. In the two's complement representation, it is evident that bit values of higher-order bits differ significantly between positive and negative values, with the value zero as a boundary. Therefore, if a signal that frequently changes between positive and negative in the vicinity of the value zero is represented, the bit-wise operation rate will be large. For instance, when a signal value changes from +1 to −1, all seven bits other than the least significant bit (LSB) change.

Meanwhile, since the most significant bit (MSB) expresses a sign and other bits a magnitude of a value in the sign magnitude representation, the difference in bit values between positive and negative values, with the value zero as a boundary, is small. Hence, the bit-wise operation rate is small even when a signal that frequently changes between positive and negative in the vicinity of the value zero is represented. For example, when the signal value changes from +1 to −1, only one bit, the most significant bit, changes. The sign magnitude representation, however, cannot represent a subtraction processing with an addition processing. Therefore, an addition processing circuit and a subtraction processing circuit must be separately prepared, which results in an increase of the scale of a circuit that implements the addition/subtraction processing. Since the circuit scale determines a load capacity C in the dynamic power dissipation P as given in Equation (1), an increase in the circuit scale increases a power dissipation. That is, compared with the two's complement representation, the sign magnitude representation can reduce the percentage-activity a, but increases the load capacity C of an addition/subtraction circuit. This results in a large power dissipation for a signal processing including a significant amount of addition/subtraction processing, in particular.

It might be conceivable to use the two's complement representation which enables efficient circuit implementation for addition/subtraction processing and use the sign magnitude representation which enables reduction of an operation rate for processing other than addition/subtraction. However, conversion between the two's complement representation and the sign magnitude representation requires bit inversion and add-one processing (increment processing). In a case of a circuit requiring a lot of conversion processing, a power dissipation increases by that of the conversion circuit.

FIG. 23 illustrates a configuration example of a conversion circuit 600 that performs conversion between the two's complement representation and the sign magnitude representation. With reference to FIG. 23, The conversion circuit 600 is configured by connecting a bit inversion circuit 601 and an add-one circuit 602. The bit inversion circuit 601 includes (D−1) XOR circuits 607 that perform an exclusive OR (XOR) operation between the most significant bit indicating a sign from an input terminal IN [D−1] and each bit from input terminals IN [i] (i=0 to D−2). The add-one circuit 602 outputs the most significant bit indicating a sign received from the input terminal IN [D−1] as it is from an output terminal OUT [D−1] while adding one to outputs of the (D−1) XOR circuits 607 and outputting the results to output terminals OUT [0] to OUT [D−2]. In the conversion circuit 600, the add-one circuit 602 in particular has a non-negligible circuit scale, compared with other logic processing circuits and operation processing circuits. Therefore, in a case where a lot of the conversion processing is required, the scale of the entire circuit and power dissipation increase by those of the conversion circuits.

Further, in FFT processing, block floating point may be used from the viewpoint of computational accuracy. In the block floating point, it is desirable that a floating-point normalization process can be applicable to data represented in formats other than the two's complement representation.

Accordingly, it is an object of the present disclosure to provide an apparatus and method, each enabled to solve at least one of the problems described above. The following discloses a signal processing apparatus and method, for instance, each enabling suppression or reduction of an increase in scale and power dissipation of an entire circuit while enabling application of a normalization process to data in a representation format other than that of the two's complement representation in block floating point.

A signal processing apparatus according to one of several aspects of the present disclosure includes an operation processing part configured to perform operation processing on data represented in a two's complement representation; and a storage processing part configured to perform storage processing on data represented in a second representation format as a data representation format.

The second representation format, while for the data of D-bits of a non-negative value being identical to the two's complement representation, for the data of D-bits of a negative value has a representation format in which (D−N−1) bits of the data of D-bits (where D is a positive integer greater than or equal to three; N is a positive integer such that N≤D−2) represented in the two's complement representation are bit-wise inverted, wherein the (D−N−1) bits are bits between a most significant bit indicating a sign and N consecutive lower bits including a least significant bit.

The storage processing part includes a normalization circuit configured to normalize a block constituted by a plurality of pieces of data, each represented in the second representation format, wherein the normalization circuit includes a maximum exponent calculation circuit configured to derive a maximum exponent from a logical operation result corresponding to a bit-wise logical OR among the plurality of pieces of data in the block for (D−1) bits excluding most significant bits of the plurality of pieces of data in the block and a shift circuit configured to perform arithmetically shift operation of the plurality of pieces of data in the block using the maximum exponent.

According to one of several aspects of the present disclosure, a signal processing method includes
performing operation processing on data represented in a two's complement representation; and
performing storage processing on data represented in a second representation format as a data representation format, wherein the second representation format, while for the data of D-bits of a non-negative value being identical to the two's complement representation, for the data of D-bits of a negative value, having a representation format in which (D−N−1) bits of the data of D-bits (where D is a positive integer greater than or equal to three; N is a positive integer such that N≤D−2) represented in the two's complement representation are bit-wise inverted, wherein the (D−N−1) bits are bits between a most significant bit indicating a sign and N consecutive lower bits including a least significant bit,
wherein the storage processing includes
normalization processing including;
for a block constituted by a plurality of pieces of data represented in the second representation format and with respect to bit strings of (D−1) bits excluding most significant bits of the plurality of pieces of D-bits data, deriving a maximum exponent from an operation result corresponding to a bit-wise logical OR among the plurality of pieces of D-bits data; and
shifting the bit strings excluding the most significant bits of the plurality of pieces of data using the maximum exponent.

According to the present disclosure, it is made possible to realize a signal processing apparatus enabling suppression or reduction of an increase in scale and power dissipation of an entire circuit while enabling application of a normalization process to data in representation format other than that of the two's complement representation in block floating point.

### BRIEF DESCRIPTION OF DRAWINGS

FIG. 1 is a diagram schematically illustrating one of several examples of signal processing apparatuses in the present disclosure.

FIG. 2 is a diagram schematically illustrating a configuration example of a storage processing part in the present disclosure.

FIG. 3 is a diagram illustrating an example of data representation formats in the present disclosure in a table format.

FIG. 4 is a diagram schematically illustrating a configuration example of a conversion circuit in the present disclosure.

FIG. 5 is a diagram schematically illustrating a configuration example of a block floating point normalization circuit in the present disclosure.

FIG. 6 is a diagram schematically illustrating a configuration example of a maximum exponent calculation circuit in the present disclosure.

FIG. 7A and FIG. 7B are diagrams schematically illustrating a configuration example and timing of a register as a non-limiting example in the present disclosure.

FIG. 8 is a diagram schematically illustrating a configuration example of a correction circuit in the present disclosure.

FIG. 9 is a diagram schematically illustrating a configuration example of a selective conversion circuit in the present disclosure.

FIG. 10 is a diagram schematically illustrating an example of an operation of the present disclosure.

FIG. 11 is a diagram schematically illustrating an example of an operation of the present disclosure.

FIG. 12 is a diagram showing an example of an effect of the present disclosure using a graph.

FIG. 13 is a diagram schematically illustrating a configuration example of a storage processing part in the present disclosure.

FIG. 14 is a block diagram illustrating a configuration example of a conversion circuit in the present disclosure.

FIG. 15 is a diagram schematically illustrating an example of an operation of the present disclosure.

FIG. 16 is a diagram schematically illustrating one of several examples of signal processing apparatuses in the present disclosure.

FIG. 17 is a diagram illustrating an example of reordering in the present disclosure.

FIG. 18 is a diagram illustrating an example of reordering in the present disclosure.

FIG. 19 is a diagram schematically illustrating a configuration example of a reordering processing part in the present disclosure.

FIG. 20 is a diagram describing an example of an operation of the data reordering processing part in the present disclosure.

FIG. 21 is a diagram illustrating an example of a 64-point FFT data flow.

FIG. 22 is a diagram illustrating an example of data representation formats in a table format.

FIG. 23 is a diagram schematically illustrating a configuration example of a conversion circuit.

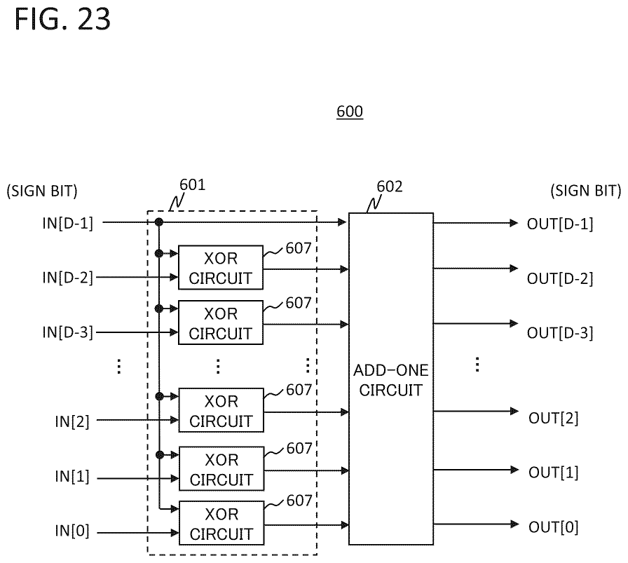

FIG. 24 is a diagram schematically illustrating a configuration example of a conversion circuit.

FIG. 25 is a diagram schematically illustrating a configuration example of a block floating point normalization circuit.

### EXAMPLE EMBODIMENTS

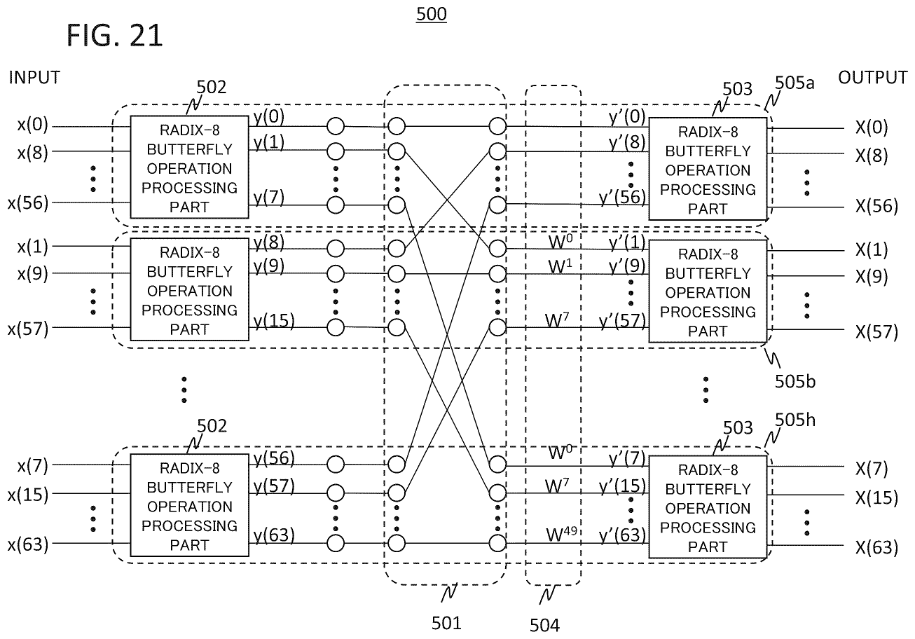

The following describes several example embodiments of the present disclosure. First, as a premise of the present disclosure, the following describes the “sign magnitude--representation” disclosed in Patent Literature 1, etc., as a data representation format for reduction of a circuit scale and power dissipation of the circuit of FIG. 21. According to Patent Literature 1, the “sign magnitude--representation” is identical to the two's complement representation when a data value is positive or zero, but all bits lower than the most significant bit indicating a sign in the two's complement representation are bit-wise inverted when the data value is negative. According to Patent Literature, 1, operation processing is performed on data represented in the two's complement representation, and storage processing is performed on data represented in the “sign magnitude--representation,” which is a second representation format as a data representation format.

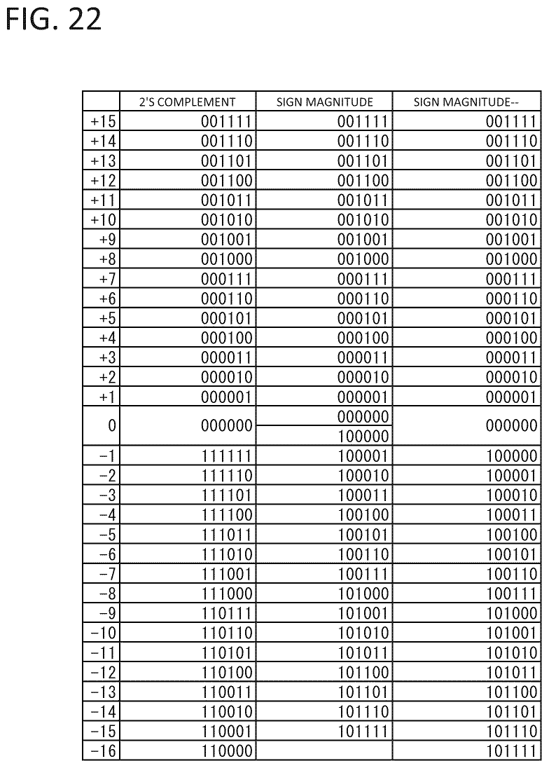

As an example of the sign magnitude—representation, in addition to the two's complement representation and the sign magnitude representation, FIG. 22 shows binary representations of signal values of +15 to −16 in 5-bit signal data. The sign magnitude—representation is identical to the two's complement representation when a data value is positive or zero, but all bits other than the most significant bit indicating a sign in the two's complement representation are bit-wise inverted when the data value is negative.

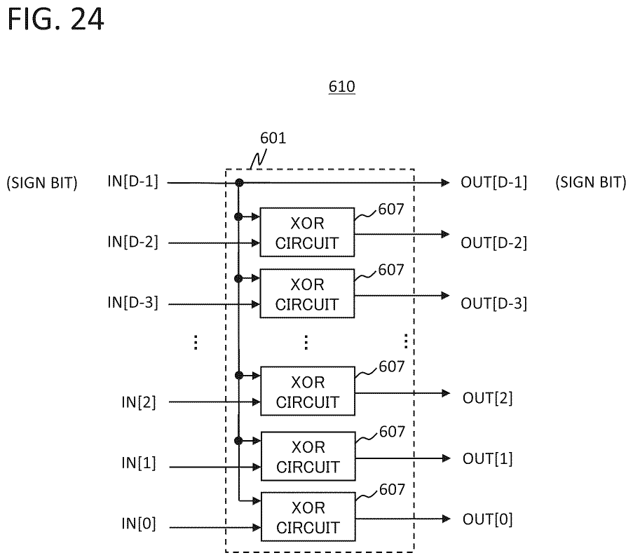

FIG. 24 schematically illustrates a configuration example of a conversion circuit 610 that performs conversion between the two's complement representation and the sign magnitude--representation. Conversion between the two's complement representation and the sign magnitude--representation can be achieved only with bit inversion processing performed by the bit inversion circuit 601, and since this does not require add-one processing performed by the add-one circuit 602, which is required by the two's complement representation and the sign magnitude representation, a circuit scale and a power dissipation of the conversion circuit can be reduced.

However, even in a case where the sign magnitude--representation is used, if the number of conversion circuits is large, the overall circuit scale and power dissipation still increase.

The sign magnitude--representation has a problem that it is difficult to use in conjunction with a lower-bit masking technique, which is one of the technologies for reducing power dissipation. The lower-bit masking technique suppresses bit transitions by fixing values of some lower bits of signal data. Although computational accuracy decreases, lower power dissipation can be expected due to reduction in bit transitions. However, if conversion processing relating to the sign magnitude—representation is performed after the lower-bit masking processing, the values of the fixed lower bits will change again and the suppression of bit transitions achieved by the lower-bit masking processing is nullified, leading to an increase in power dissipation.

In digital signal processing, floating-point arithmetic has an advantage of allowing high-accuracy calculations even when dealing with signal data taking a wide range of values. On the other hand, it requires complex circuitry, which leads to larger circuit scale and higher power dissipation. Fixed-point arithmetic, by contrast, offers benefits of simpler circuitry, smaller circuit scale, and lower power dissipation, but comes with a drawback of reduced computational accuracy. Block floating point arithmetic is an arithmetic method that combines the advantages of both floating-point and fixed-point arithmetic.

In block floating point arithmetic, a plurality of pieces of signal data are grouped into a single block, and an entire block is normalized so that each block has a common exponent. Meanwhile, floating-point normalization shifts the mantissa (to the right) so that the most significant digit becomes a non-zero value. Block floating point normalization shifts the mantissa using a common exponent shared across an entire block.

In block floating point processing, for instance, the following steps are taken to perform block floating point normalization (Reference Literature 3):
(1) Find a maximum exponent for all pieces of data within a block.
(2) Shift (normalize) the entire block using the maximum exponent.

Here, the maximum exponent refers to the largest exponent that does not cause any of the data within the block to overflow. The maximum exponent is equal to the exponent of the data with the largest absolute value among all pieces of data in the block.

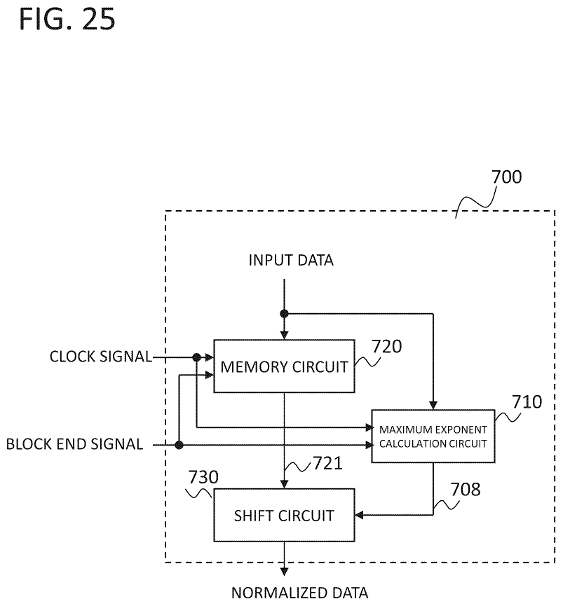

FIG. 25 schematically illustrates a configuration example of a block floating point normalization circuit (hereinafter referred to as “normalization circuit”) (Reference Literature 3). The normalization circuit 700 performs block floating point normalization processing on each piece of input data that constitutes a block. The normalization circuit 700 outputs each piece of data obtained by normalizing each piece of input data as each piece of normalized data.

In FIG. 25, the normalization circuit 700 has a memory circuit 720, a maximum exponent calculation circuit 710, and a shift circuit 730.

The maximum exponent calculation circuit 710 calculates a maximum exponent for input data received. The maximum exponent calculation circuit 710 outputs the calculated maximum exponent as a maximum exponent 708 to the shift circuit 730.

The memory circuit 720 holds input data received while the maximum exponent calculation circuit 710 calculates the maximum exponent of the input data. Input data is sequentially supplied to each of the memory circuit 720 and the maximum exponent calculation circuit 710 from, for instance, an external apparatus (not shown the drawing). The memory circuit 720 sequentially holds input data supplied by an external apparatus. Further, the memory circuit 720 sequentially outputs the input data held therein as input data 721 to the shift circuit 730 after the maximum exponent calculation circuit 710 has calculated the maximum exponent.

The shift circuit 730 performs normalization processing by shifting the input data outputted by the memory circuit 720 based on the maximum exponent 708 calculated by the maximum exponent calculation circuit 710.

The normalization circuit 700 operates on a premise that at least the mantissa of input data in block floating point is represented using the two's complement representation. The block floating point normalization in the normalization circuit 700 is performed on a part (a part of pieces of input data) that uses two's complement representation. Input data represented in a format(s) other than the two's complement representation is converted to the two's complement representation and then normalized.

As described, in the normalization circuit 700 of FIG. 25, normalization processing is limited to a part(s) that uses the two's complement representation. Therefore, input data represented in a format(s) other than the two's complement representation is converted to the two's complement representation before subjected to normalization processing. This necessitates a conversion circuit that performs conversion to the two's complement representation.

The above issues are merely examples, and the present disclosure discloses several example embodiments of a signal processing apparatus that address the above issues.

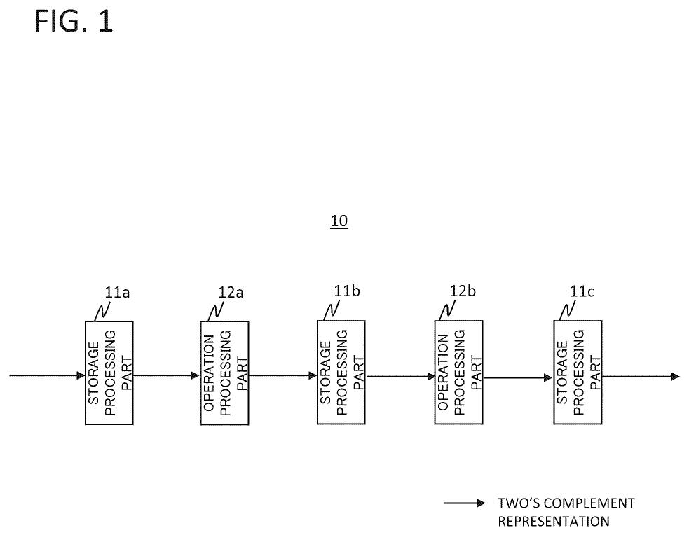

FIG. 1 is a diagram schematically illustrating one of several example embodiments of the signal processing apparatus 10 of the present disclosure. With reference to FIG. 1, the signal processing apparatus 10 include s storage processing parts 11a, 11b, and 11c that may perform storage processing such as buffering signal data, re-timing and reordering processing, and operation (arithmetic operation) processing parts 12a and 12b that may perform operation (arithmetic operation) processing such as addition/subtraction and multiplication/division. FIG. 1 illustrates a flow of data in processing. The storage processing parts 11a, 11b, and 11c may be referred to as the storage processing parts 11 with the signs a, b, and c omitted except when each part is specified in the description. The same applies to other elements.

The storage processing part 11a receives signal data, in which at least the mantissa of block floating point data is represented in the two's complement representation, from outside (not shown in the drawing) of the signal processing apparatus 10, performs storage processing, and outputs the result to the operation processing part 12a. In the present disclosure, “signal data in which at least the mantissa of block floating point data is represented in the two's complement representation” is also referred to as “signal data represented in the two's complement representation.”

The operation processing part 12a receives the signal data represented in the two's complement representation from the storage processing part 11a, performs operation processing, and outputs a result to the storage processing part 11b.

The storage processing part 11b receives the signal data represented in the two's complement representation from the operation processing part 12a, performs storage processing, and outputs the result to the operation processing part 12b.

The operation processing part 12b receives the signal data represented in the two's complement representation from the storage processing part 11b, performs operation processing, and outputs a processing result to the storage processing part 11c.

The storage processing part 11c receives the signal data represented in the two's complement representation from the operation processing part 12b, performs storage processing, and outputs the result to the outside of the signal processing apparatus 10.

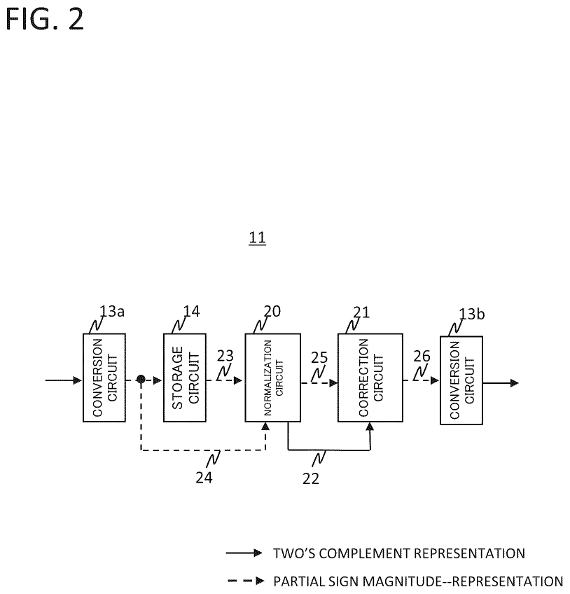

The storage processing parts 11a, 11b, and 11c have a common circuit configuration, and for example, they can be realized by a storage processing part 11 illustrated in FIG. 2. With reference to FIG. 2, the storage processing part 11 includes a first conversion circuit 13a, a storage circuit 14, a normalization circuit 20, a correction circuit 21, and a second conversion circuit 13b.

In the storage processing part 11, the first conversion circuit 13a is configured to receive signal data represented in the two's complement representation, convert the data to signal data represented in “partial sign magnitude--representation,” and output the result. It is noted that the “partial sign magnitude—representation” is a term that is used solely herein and is not a common technical term. A “partial sign magnitude--representation” corresponds to a “second representation format” in the Claims.

The partial sign magnitude--representation is identical to the two's complement representation when a data value of D bits (D is a positive integer greater than or equal to three) is positive or zero. In the partial sign magnitude--representation, (D−N−1) bits in the two's complement representation are bit-wise inverted except for the most significant bit (MSB) indicating a sign and the consecutive lower N bits (N is a positive integer such that N≤D−2) including the least significant bit (LSB) when a data value of D bits is negative. That is, in the “partial sign magnitude--representation,” the consecutive lower N bits including the least significant bit (LSB) in D-bits data are identical to the two's complement representation, and (D−N−1) bits between the most significant bit (MSB) and the consecutive lower N bits including the least significant bit (LSB) are identical to the “sign magnitude--representation.” Hereinafter, the value of N is denoted as the “number of unconverted bits” and is treated as one of parameters that define the “partial sign magnitude-representation.”

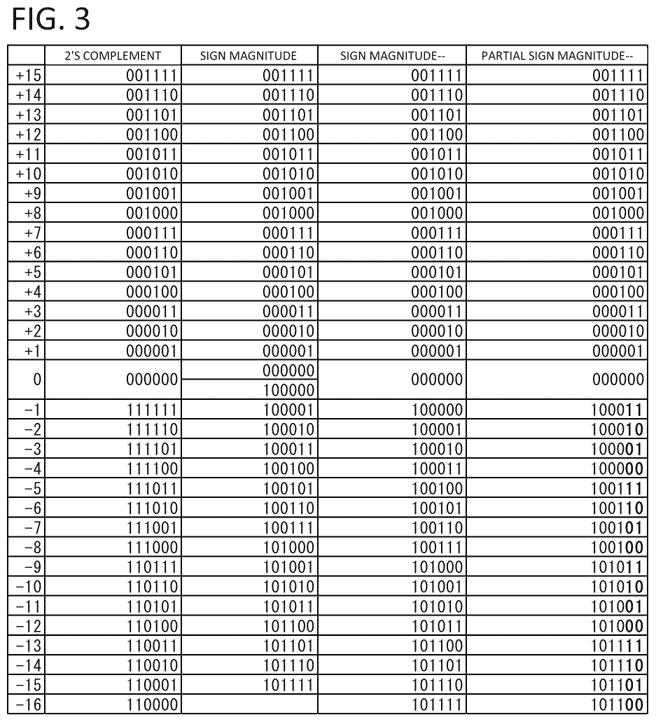

FIG. 3 shows the binary representations of +15 to −16 signal values in 6-bits signal data (the number of data bits D=6; the number of unconverted bits N=2) in the “partial sign magnitude--representation” and those in the two's complement representation, the sign magnitude representation, and the “sign magnitude--representation” as a comparison. In FIG. 3, positive data values are represented by the same bit values in the “partial sign magnitude--representation,” the two's complement representation, the sign magnitude representation, and the “sign magnitude--representation.”

The data value zero is represented by the same bit value in the partial sign magnitude--representation and the two's complement representation.

When a data value is negative, the partial sign magnitude--representation is obtained by inverting remaining three bits in the two's complement representation, after excluding the most significant bit (MSB) indicating a sign and two lower bits including the least significant bit (LSB) ((D−N−1) bits between MSB and the two lower bits including LSB=(6−2−1) bits).

Similarly, when a data value is negative, the two's complement representation is obtained by inverting the remaining three bits in the partial sign magnitude—representation, after excluding the most significant (MSB) bit indicating a sign and the two lower bits including the least significant bit (LSB) ((D−N−1) bits between MSB and the two lower bits including LSB=(6−2−1) bits). Therefore, when a data value is negative, the difference between the partial sign magnitude—representation and the sign magnitude--representation is the two lower bits including the least significant bit (LSB).

As illustrated in FIG. 3, with the value zero as a boundary, the difference in bit values between positive and negative values is small in the partial sign magnitude--representation, as in the sign magnitude representation and the sign magnitude--representation. Therefore, when a signal whose value frequently changes between positive and negative in the vicinity of zero is represented, the bit-wise operation rate is small.

For instance, when a signal value changes from +1 to −1, since it changes from +1 (“000001”) to −1 (“100011”) in the partial sign magnitude—representation, a total of two bits changes: the most significant bit and the bit second to the least significant bit.

Since the signal value changes from +1 (“000001”) to −1 (“111111”) in the two's complement representation, a total of five bits other than the least significant bit changes.

In the sign magnitude--representation, a change from +1 (“000001”) to −1 (“100000”) entails two changed bits in total: the most significant bit and the least significant bit.

With reference to FIG. 2 again, the storage circuit 14 is configured to receive signal data represented in the partial sign magnitude--representation outputted by the first conversion circuit 13a, perform storage processing while staying in the partial sign magnitude—representation, and output the result to the normalization circuit 20 in the partial sign magnitude—representation.

The normalization circuit 20 is configured to perform block floating point normalization on signal data represented in the partial sign magnitude—representation.

The normalization circuit 20 is configured to receive signal data 23, outputted by the storage circuit 14, after the storage processing, and signal data 24, outputted by the first conversion circuit 13a, before the storage processing, perform normalization processing thereon, and output normalized data 25 after the normalization and a maximum exponent 22 indicating an amount of shift in the normalization processing to the correction circuit 21.

The correction circuit 21 is configured to refer to the maximum exponent 22 and correct bit position(s) identical to those in the two's complement representation and bit position(s) identical to those in the sign magnitude--representation in the normalized data 25, in the partial sign magnitude--representation which has been normalized by the normalization circuit 20, so as to be the same as those before the normalization processing. The correction circuit 21 is configured to output corrected data 26, which is signal data after the correction processing, to the second conversion circuit 13b.

The second conversion circuit 13b is configured to convert the corrected data 26 represented in the partial sign magnitude--representation and outputted by the correction circuit 21 to signal data represented in the two's complement representation and outputs the result.

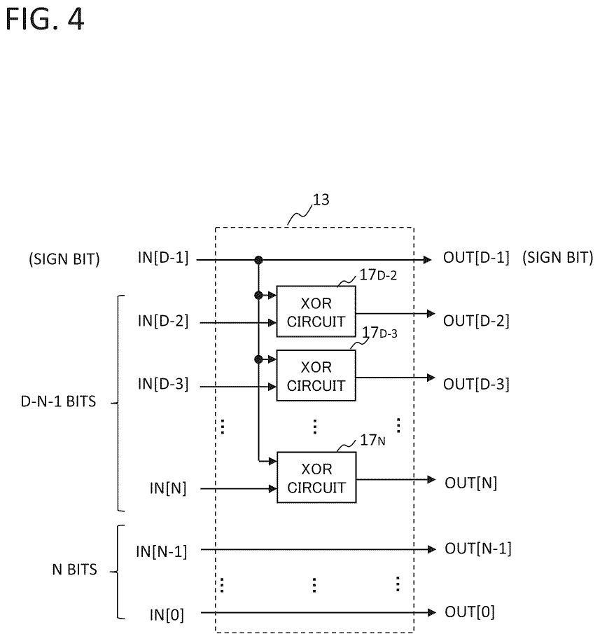

The first and the second conversion circuits 13a and 13b may have identical arrangement and can be realized by a conversion circuit 13 illustrated in FIG. 4 for example. The first and the second conversion circuits 13a and 13b will be referred to as the conversion circuit 13 when there is no need to distinguish them from each other. With reference to FIG. 4, the conversion circuit 13 receives in parallel D-bits (D is a positive integer greater than or equal to three) signal data (IN[0] to IN[D−1]) in the two's complement representation, converts the two's complement representation to the partial sign magnitude--representation, and outputs the resultant D-bits data (OUT[0] to OUT[D−1]) in parallel.

Further, the conversion circuit 13 is configured to receive in parallel D-bits signal data (IN[0] to IN[D−1]) in the partial sign magnitude--representation, convert the partial sign magnitude--representation to the two's complement representation, and output the resultant D-bits data (OUT[0] to OUT[D−1]) in parallel.

The conversion circuit 13 is configured to receive the most significant bit (MSB) indicating a sign from the input IN[D−1] and output as it is to OUT[D−1] as a sign bit.

The conversion circuit 13 is configured to output consecutive lower N bits including the least significant bit (LSB) received from the inputs IN[0] to IN [N−1], as they are, to the outputs OUT[0] to OUT[N−1], respectively.

The conversion circuit 13 is configured to supply bits received from the inputs IN[N] to IN[D−2] to XOR (Exclusive OR) circuits 17ᵢ (i=N to D−2), respectively, and outputs results of XORs between the most significant bit (MSB) indicating a sign received from the input IN[D−1] and respective ones of the bits supplied to the XOR (Exclusive OR) circuits 17ᵢ to the outputs OUT [N] to OUT[D−2], respectively.

When an input data value is positive or zero, the value of the most significant bit (MSB) indicating a sign received from the input IN[D−1] is zero, and the bit values supplied to the inputs IN[0] to IN[D−2] are outputted as they are to the outputs OUT[0] to OUT[D−2], respectively.

Conversely, when an input data value is negative, the value of the most significant bit (MSB) received from the input IN[D−1] and indicating a sign is one, and the bit values supplied to the inputs IN[0] to IN [N−1] are outputted as they are to the outputs OUT[0] to OUT[N−1], respectively. Values obtained by inverting the respective bit values supplied to the inputs IN[N] to IN[D−2] using the XOR circuits 17_{N} to 17_{D-2} are outputted to the outputs OUT [N] to OUT[D−2], respectively.

In the processing described above, the conversion circuit 13 converts the two's complement representation to the partial sign magnitude--representation and convert the partial sign magnitude--representation to the two's complement representation.

As described above, the conversion circuit 13 achieves conversion between the two's complement representation and the partial sign magnitude—representation only with bit inversion processing and does not require add-one processing, which is required for conversion between the two's complement representation and the sign magnitude representation. Since bit inversion can be implemented with exclusive OR operation (XOR circuit), this can be realized with an overwhelmingly small circuit scale, as compared with other logic processing circuits and operation processing circuits.

Further, the number of the XOR circuits 17_{N} to 17_{D-2} in the conversion circuit 13 is D−N−1, and this is smaller as compared with conversion between the two's complement representation and the sign magnitude—representation. Therefore, the scale of the conversion circuit 13 can be reduced accordingly.

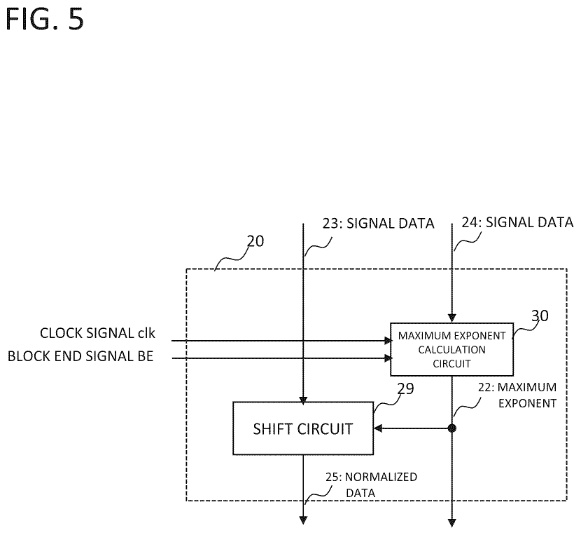

With reference to FIG. 5, the following describes a block floating point normalization circuit. FIG. 5 is a diagram schematically illustrating a configuration example of a block floating point normalization circuit (hereinafter referred to as normalization circuit) relating to an example embodiment of the present disclosure. In FIG. 5, the normalization circuit 20 performs normalization processing in block floating point on each piece of the signal data 23 constituting a block. The normalization circuit outputs data obtained by normalizing input data as the normalized data 25.

In FIG. 5, the normalization circuit 20 includes a maximum exponent calculation circuit 30 and a shift circuit 29. The maximum exponent calculation circuit 30 is configured to calculate the maximum exponent 22 for the supplied signal data 24 and output the calculated maximum exponent to the shift circuit 29. The shift circuit 29 is configured to perform normalization processing by arithmetically shifting the signal data 23 based on the maximum exponent 22 calculated by the maximum exponent calculation circuit 30. In an arithmetic shift, a bit string excluding a sign bit (the most significant bit) is shifted; the sign bit is not shifted. Any overflow bit as a result of the shift is discarded, and empty position(s) are filled with zero(s). The shift circuit 29 of the floating-point hardware circuit may be constituted by, for example, a barrel shifter. The barrel shifter arithmetically shifts the signal data 23 by the number of bits corresponding to the maximum exponent 22 in a single clock cycle. (With n being an integer equal to or greater than two, an n-bit shift does not require n clock cycles.)

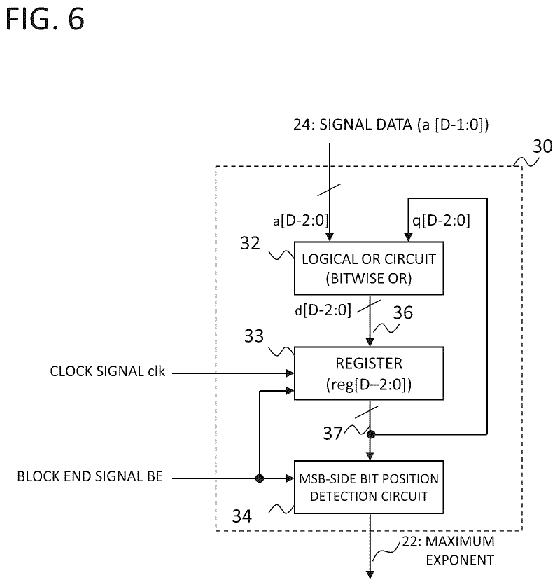

FIG. 6 is a diagram schematically illustrating a configuration of the maximum exponent calculation circuit 30. With reference to FIG. 6, with respect to a block constituted by a plurality of pieces of the signal data 24, the maximum exponent calculation circuit 30 is configured to calculate a maximum exponent for all pieces of data within the block. At this time, the maximum exponent calculation circuit 30 is configured to refer to an input block end signal BE to identify the end of the block. For instance, the block end signal is supplied to the maximum exponent calculation circuit 30 from an external circuit (not shown in the drawing). The external circuit outputs an asserted block end signal BE to the maximum exponent calculation circuit 30 in a cycle in which the last input data in the block is outputted to the maximum exponent calculation circuit 30.

The maximum exponent calculation circuit 30 includes a logical OR circuit 32, a register 33, and an MSB-side bit position detection circuit 34 as main circuits.

The logical OR circuit 32 is configured to perform a bit-wise OR operation between lower D−1 bits of the input D-bits signal data 24, excluding the sign bit, and a (D−1)-bits register value 37 outputted by the register 33 and then output the calculated OR value to the register 33 as a logical OR value 36. For instance, for the signal data 24 (a[D−1:0]) with a bit width of D, the logical OR circuit 32 receives the lower D−1 bits a[D−1:0] of the signal data 24 and data q[D−1:0] with a bit width of D−1 outputted from the register 33. The logical OR circuit 32 includes, for instance, (D−1) two-input OR circuits (not shown in the drawing). The i-th OR circuit (i=0, . . . , D−2) performs an operation d[i]=OR(a[i], q[i]) (i=0, . . . , D−2) and (D−1)-bits logical OR value 36 (d[D−2:0]) are outputted in parallel.

The register 33 may include a circuit that latches and outputs the logical OR value 36 (d[D−2:0]) outputted by the logical OR circuit 32 for each operation cycle based on a clock signal clk generated by a clock generator (not shown in the drawing). In this case, the register 33 may be constituted by a register that captures the logical OR value 36 (d[D−2:0]) outputted by the logical OR circuit 32, for example, in response to the clock signal clk and latches and outputs the captured value. The register 33 outputs the held logical OR value as the register value 37 to the logical OR circuit 32 and the MSB-side bit position detection circuit 34 for each clock cycle. Further, the register 33 is configured to receive the block end signal BE generated by a control circuit (not shown in the drawing). When the block end signal BE becomes active (for instance, at high level), the register 33 is configured to recognize a final operation cycle in which a final logical OR value 36 based on the last input data of the block is supplied from the logical OR circuit 32 to the register 33. The register 33 may be configured to reset the register value 37 (logical OR value) held for each block to an initial value of zero in a cycle following the final operation cycle of each block. In this case, the register 33 resets the value latched to zero after having outputted the final register value 37 (the final logical OR value of each block) to the MSB-side bit position detection circuit 34.

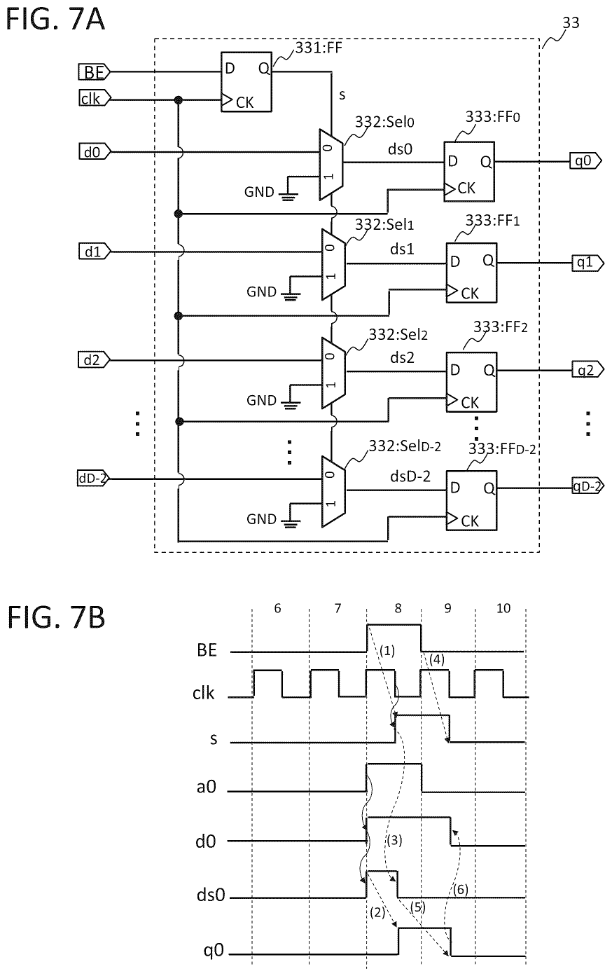

FIG. 7A is a diagram schematically illustrating a non-limiting configuration example of the register 33. FIG. 7A schematically illustrates a circuit example where input data (the logical OR value 36 outputted by the logical OR circuit 32) is eight bits (D=8). In the n-th cycle (clock cycle), the register 33 captures, latches and outputs the logical OR value 36, which is a result of the most recent logical operation performed by the logical OR circuit 32, and the logical OR circuit 32 performs a logical OR operation between the signal data 24 in the n-th cycle and the register value 37 outputted by the register 33 and outputs the operation result as a new logical OR value 36. As schematically illustrated in FIG. 7A, the register 33 includes a flip-flop 331 (FF) that receives the block end signal BE from a data terminal D thereof, captures a value at the data terminal D based on the clock signal clk, and outputs the captured value from an output terminal Q; (D−1) selectors 332 (Sel₀ to Sel_{D-2}) that receive the output of the flip-flop 331 as a selection signal s, select input data d0 to dD−2, respectively, when the selection signal s is 0, and output a fixed value of 0 (low level; ground (GND) level) when the selection signal s is 1; and (D−1) flip-flops 333 (FF₀ to FF_{D-2}) that receive output signals ds0 to dsD−2 of the (D−1) selectors 332 (Sel₀ to Sel_{D-2}) from respective data terminals D thereof, capture values at the terminals D based on the clock signal clk, and output the captured values from output terminals Q thereof.

FIG. 7B is a timing diagram illustrating a non-limiting operation example of the register of FIG. 7A when eight consecutive pieces of data is one block and schematically shows examples of the block end signal BE, the clock signal clk, the selection signal s, the least significant bit a0 of the signal data 24, the least significant bit d0 of the logical OR value 36 outputted by the logical OR circuit 32, the output ds0 of the selector 332 (Sel₀), and a timing waveform of an output q0 of the flip-flop 333 (FF₀). In order to simplify the explanation, the flip-flops 331 and 333 are illustrated as master-slave flip-flops in which a value at the data terminal D is captured by a master flip-flop (not shown in the drawing) when the clock signal clk is high (or when it rises from low to high), and an output of the master flip-flop (not shown in the drawing) is captured by a slave flip-flop (not shown in the drawing) and outputted from the output terminal Q when the clock signal clk is low (or when it falls from high to low) (the value at the output terminal Q is held and hold and outputted until the clock signal clk goes low again.). The flip-flops 331 and 333 are, as a matter of course, not limited to the master-slave flip-flops described above.

In a given cycle, the logical OR value 36 outputted by the logical OR circuit 32 is a logical OR between the signal data 24 in that cycle and the register value 37 held and outputted by the register 33 (which is the logical OR value 36 outputted by the logical OR circuit 32 in the immediately preceding cycle). FIG. 7B shows an example in which the least significant bit (LSB) a0 of the signal data 24 is zero in cycles 5 to 7 and 1 in cycle 8. This is to clarify an operation when the block end signal BE is asserted in the cycle 8. A high level in the waveform is represented as 1, and a low level as 0.

In the cycle 8, the block end signal BE goes to 1, and the least significant bit a0 of the signal data 24 goes to 1. When the block end signal BE transitions from 0 to 1 in the cycle 8, the flip-flop 331 sets the output Q (=the selection signal s) to 1 on a falling edge of the clock signal clk (dashed arrow (1)). Note that the selection signal s is 0 until immediately before the falling edge of the clock signal clk in the cycle 8, and the selector 332 (Sel₀) selects and outputs the least significant bit d0 of the logical OR value 36 outputted by the logical OR circuit 32. A terminal q0 connected to the output terminal Q of the flip-flop 333 (FF₀) is at 0 until the cycle 8. Since the least significant bit a0 of the signal data 24 becomes 1 in the cycle 8, the least significant bit d0 of the logical OR value 36 outputted by the logical OR circuit 32 transitions from 0 to 1. The selection signal s is 0 until immediately before the falling edge of the clock signal clk in the cycle 8, and the output ds0 of the selector 332 (Sel₀), which heretofore has selected d0, transitions from 0 to 1 in the cycle 8. The flip-flop 333 (FF₀) captures ds0 (=1) when the clock signal clk is high in the cycle 8, and the terminal q0 connected to the output terminal Q of the flip-flop 333 (FF₀) is at 1 on the falling edge of the clock signal clk in the cycle 8 (dashed arrow (2)).

When the selection signal s goes to 1 on the falling edge of the clock signal clk in the cycle 8, the selector 332 (Sel₀) selects the low level (fixed value 0) and the output ds0 thereof becomes 0 (dashed arrow (3)).

The output ds0 (=0) of the selector 332 (Sel₀) is captured by the flip-flop 333 (FF₀) on a transition of the clock signal clk to the high level in cycle 9, and on a falling edge of the clock signal clk in the cycle 9, the flip-flop 333 (FF₀) sets the terminal q0, connected to the output terminal Q, to 0 (dashed arrow (5)). That is, the output (the register value 37) of the flip-flop 333 (FF₀) of the register 33 is reset to 0 on the falling edge of the clock signal clk in the cycle 9. In the cycle 9, the least significant bit a0 of the signal data 24 is 0, and the least significant bit q0 of the register value 37 becomes 0 on the falling edge of the clock signal clk in the cycle 9. Therefore, d0, which is the logical OR between the least significant bit a0 of the signal data 24 and the least significant bit q0 of the register value 37, changes from 1 to 0 (dashed arrow (6)).

Although the least significant bit a0 of the signal data 24 is 0 in the cycle 9, the least significant bit d0 of the logical OR value 36 outputted by the logical OR circuit 32 is 1 because the terminal q0 connected to the output terminal Q of the flip-flop 333 (FF₀) of the register 33 is at 1 in the first half of the cycle 9. On the falling edge of the clock signal clk in the cycle 9, the selection signal s, which is the output of the flip-flop 331, changes from 1 to 0 (dashed arrow (4)). The flip-flops 333 (FF₀ to FF_{D-2}) capture the outputs d0 to dD−2 of the logical OR circuit 32 during the second half of the cycle 8 (when the clock signal clk is at the low level), hold and output the register value 37 as the final logical OR value of the block until the falling edge of the clock signal clk in the cycle 9, and send the register value 37 to the MSB-side bit position detection circuit 34.

In the cycle 9, the MSB-side bit position detection circuit 34 receives and latches the register value 37 (the final logical sum value 36 of the block) outputted by the register 33. The MSB-side bit position detection circuit 34 detects a first bit position at which the bit string constituting the register value 37 transitions from 0 to 1, starting from the most significant bit. The MSB-side bit position detection circuit 34 calculates and outputs the maximum exponent 22 based on the detected bit position. More specifically, if, counting from the MSB side with the MSB as a zeroth bit, the value of the M-th bit (where M is an integer of zero or more) in the register value 37 outputted by register 33 is one, the MSB-side bit position detection circuit 34 outputs (−1×M) as a maximum exponent. For instance, if the value of the first bit of the register value 37, counting from the MSB side, is one, then, for remaining (D−1) bits excluding the sign bit (MSB), the value of the zeroth bit from the MSB is 0 in all the input data. In this case, the value of the first bit from the MSB in the remaining bit string excluding the sign bit (MSB) is one in at least one piece of the input data. Therefore, according to the aforementioned formula (−1×M), a maximum exponent corresponding to a shift amount that allows normalized values to be correctly represented without changing any sign of the input data can be calculated as −1×1=−1.

Here, although the register 33 outputs the register value 37 in each operation cycle, the MSB-side bit position detection circuit 34 calculates the maximum exponent 22 based on the register value 37 indicating the final logical OR value of each block. The MSB-side bit position detection circuit 34 refers to the block end signal BE to recognize a cycle in which the register 33 outputs the register value 37 indicating the final logical OR value of each block. The MSB-side bit position detection circuit 34 may include a register (not shown in the drawing) that captures, latches and outputs the register value 37 based on a signal obtained by sampling the block end signal BE using the clock signal clk and may identify an MSB-side bit position from the held register value 37. As described above, after the register value 37 indicating the final logical OR value of the block is captured by the MSB-side bit position detection circuit 34 in the cycle 8, the register 33 is reset and the register value 37 (q[D−2:0]) is set to 0 in the cycle 9.

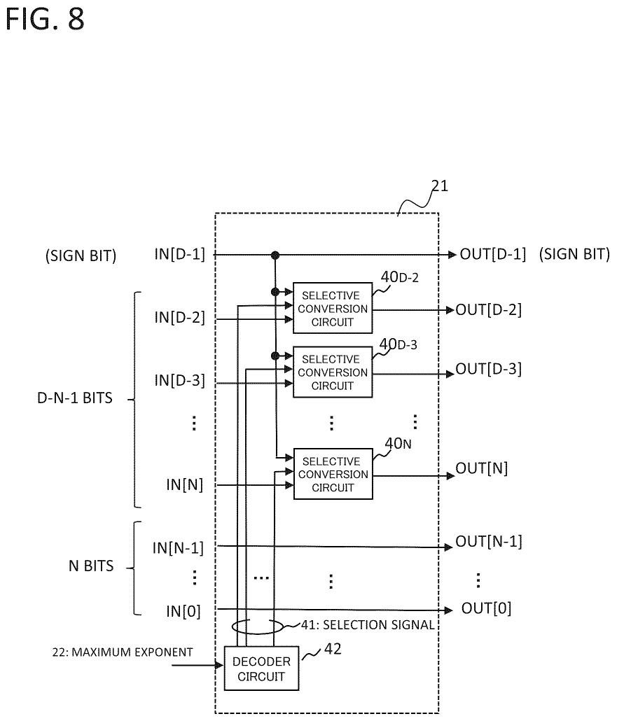

With reference to FIG. 2 again, the correction circuit 21 can be implemented, for example, using a configuration illustrated in FIG. 8. With reference to FIG. 8, the correction circuit 21 includes a plurality of selective conversion circuits 40 and a decoder circuit 42. The correction circuit 21 is configured to correct the value of N (the number of unconverted bits) in the signal data represented in the partial sign magnitude—representation and normalized by the normalization circuit 20 to the same value as before the normalization processing.

More specifically, the correction circuit 21 is configured to output the most significant bit indicating a sign supplied from the input IN[D−1] as it is to OUT[D−1] as a sign bit. N consecutive lower bits including the least significant bit (LSB) supplied from the inputs IN[0] to IN[N−1] are outputted as they are to the outputs OUT[0] to OUT[N−1], respectively. For (D−N−1) bits supplied form the inputs IN[N] to IN[D−2], each selective conversion circuit 40, based on a selection signal 41, chooses either to output the input as it is, or to output it after bit inversion using an exclusive OR operation with the most significant bit (MSB) indicating a sign, supplied from the input IN[D−1], to the outputs OUT[N] to OUT[D−2], respectively.

The decoder circuit 42 is configured to refer to the maximum exponent 22 outputted by the normalization circuit 20 and control each of the plurality of selective conversion circuits 40 whether to output the input data as it is or output bit-inverted data using an exclusive OR operation with the most significant bit indicating a sign, supplied from the input IN[D−1]. The decoder circuit 42 is configured to output the selection signal 41 that correct the number N of unconverted bits in the signal data received to the same value as before the normalization processing. (D−N−1) selective conversion circuits 40_{N} to 40_{D-2} are provided corresponding to (D-N−1) bits between the most significant bit (MSB) and N consecutive lower bits including the least significant bit (LSB), and the decoder circuit 42 decodes the maximum exponent 22 and outputs a decoded result with (D−N−1) selection signals 41 to the (D−N−1) selective conversion circuits 40_{N} to 40_{D-2}. Without being limited thereto, for instance, when the maximum exponent 22 is −M (a right shift by M bits, where M≤(D−N−1)), the decoder circuit 42 may decode M and output (D−N−1) selection signals 41 that select the selective conversion circuits 40_{N} to 40_{N+M-1}, connected to M lower bits IN[N] to IN[N+M−1], respectively, while setting the remaining selective conversion circuits 40 to an unselected state.

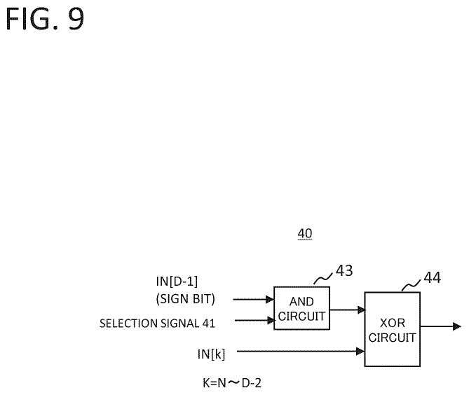

For instance, the selective conversion circuit 40 can be realized with a configuration shown in FIG. 9. With reference to FIG. 9, the selective conversion circuit is constituted by an AND circuit 43 and an XOR circuit 44. When a value of the selection signal 41 is 0, an output of the AND circuit 43 is always 0, causing the selective conversion circuit 40 to pass input data through unchanged. When a value of the selection signal 41 is one, the selective conversion circuit 40 outputs a result of an exclusive OR operation performed by the XOR circuit 44 using a sign bit supplied from the input IN[D−1]since an output of the AND circuit 43 is the value of the sign bit (IN[D−1]).

Using the processing described above, the correction circuit 21 corrects the signal data 24 in the partial sign magnitude--representation in which the number N of unconverted bits is changed by the normalization circuit 20 so that the number N of unconverted bits is the same as that in the partial sign magnitude--representation before the normalization processing. The normalization circuit 20 changes the number N of unconverted bits in the signal data 24 in the partial sign magnitude--representation. As a result, the conversion circuit 13b cannot correctly convert the signal data 24 in the partial sign magnitude—representation outputted by the normalization circuit 20 back to the two's complement representation as it is. Therefore, by having the correction circuit 21 correct the data obtained by normalizing the signal data in the partial sign magnitude--representation, which is converted from the two's complement representation by the conversion circuit 13a in FIG. 2, the data can be converted back to the two's complement representation by the conversion circuit 13b in FIG. 2.

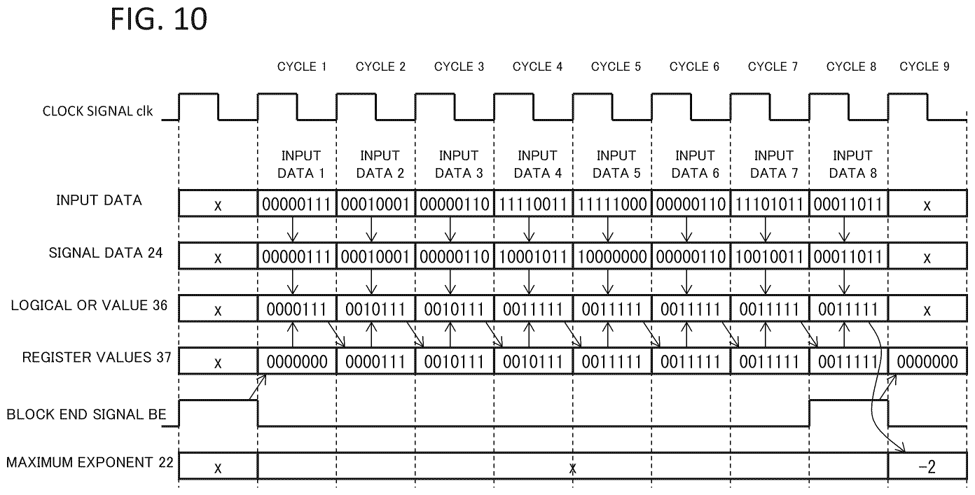

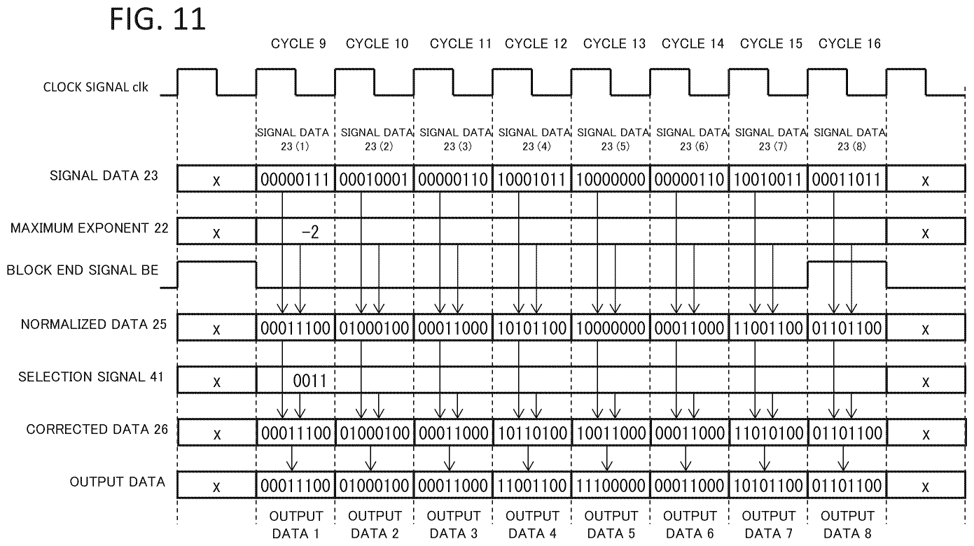

The following describes an example of an operation of the storage processing part 11 with reference to FIGS. 10 and 11. FIGS. 10 and 11 are timing diagrams showing an example of an operation of the storage processing part 11. The storage processing part 11 operates based on a supplied clock signal.

As an example of a signal data block in block floating point constituted by a plurality of pieces of signal data to be processed, a block having a mantissa constituted by the following eight pieces of data, input data 1 to 8, will be described. Each input data is eight bits (In[D−1, 0], D=8). The following shows the value of each data in the two's complement representation. In each bit string of data shown below, the leftmost bit represents the MSB, and the rightmost bit the LSB. The MSB is a sign bit.
Input data 1: 00000111
Input data 2: 00010001
Input data 3: 00000110
Input data 4: 11110011
Input data 5: 11111000
Input data 6: 00000110
Input data 7: 11101011
Input data 8: 00011011

With reference to FIG. 10, the storage processing part 11 sequentially receives the input data 1 to 8 during first to eighth operation cycles (cycles 1 to 8). In a cycle immediately preceding the cycle 1, X represents a don't-care. The conversion circuit 13a converts the input data 1 to 8 represented in the two's complement representation to the partial sign magnitude—representation during the cycles 1 to 8 and outputs results as signal data 24 (1) to 24 (8). It is assumed that in the partial sign magnitude--representation, the number of data bits (D) is eight bits, and the number of unconverted bits (N) is three bits.

The conversion circuits 13a and 13b perform conversion processing corresponding to the number N of unconverted bits (=3). Therefore, in the signal data 24 (1) to 24 (8), when the MSB is one, three consecutive lower bits including the least significant bit (LSB) in eight-bits data are identical to the two's complement representation and five remaining consecutive higher bits including the most significant bit (MSB) are identical to the sign magnitude--representation. More specifically, the values are as follows:
Signal data 24 (1): 00000111
Signal data 24 (2): 00010001
Signal data 24 (3): 00000110
Signal data 24 (4): 10001011
Signal data 24 (5): 10000000
Signal data 24 (6): 00000110
Signal data 24 (7): 10010011
Signal data 24 (8): 00011011

In the signal data 24 (4), 24 (5), and 24 (7), N (3) lower bits including the LSB of the input data are unconverted, and each of (D−N−1) (=4) higher bits are inverted from the input data.

The storage circuit 14 receives and stores the signal data 24 (1) to 24 (8) during the cycles 1 to 8.

With reference to FIG. 10, the following describes operations of the normalization circuit 20 and the correction circuit 21 for each cycle.

### (Cycle 1)

In the first operation cycle (the cycle 1) in the normalization circuit 20, the maximum exponent calculation circuit 30 receives the signal data (1). The logical OR circuit 32 that constitutes the maximum exponent calculation circuit 30 calculates a logical OR between seven bits excluding the sign bit (MSB) in the signal data (1) and a register value 37 (1) outputted by the register 33. The logical OR circuit 32 outputs the calculated logical OR as a logical OR value (1) to the register 33. Here, in the cycle 1, the register value 37 (1) is an initial value of zero.
The logical OR value 36 (1): 0000111

The register 33 latches the logical OR value 36 (1) outputted by the logical OR circuit 32 in the cycle 1. The register 33 may be configured to capture and hold the logical OR value 36 (1) outputted by the logical OR circuit 32 in the cycle 1 on a rising edge of the clock signal in the cycle 2. The register 33 outputs the logical OR value 36 (1) held therein as a register value 37 (2) in the cycle 2, which is the next operation cycle.

### (Cycle 2)

In the second operation cycle (the cycle 2), the maximum exponent calculation circuit 30 receives the signal data (2). The logical OR circuit 32 that constitutes the maximum exponent calculation circuit 30 calculates a logical OR between seven bits excluding the sign bit (MSB) in the signal data (2) and the register value 37 (2) (the logical OR value 36 (1) outputted by the logical OR circuit 32 in the cycle 1) outputted by the register 33 and outputs the calculated logical OR as a logical OR value 36 (2) to the register 33. Here, the register value 37 (2) in the cycle 1 is the logical OR value 36 (1) latched in the cycle 1.
The logical OR value 36 (2): 0010111

The register 33 latches the logical OR value 36 (2) outputted by the logical OR circuit 32 in the cycle 2. The register 33 may be configured to capture and hold the logical OR value 36 (1) outputted by the logical OR circuit 32 in the cycle 2 on a rising edge of the clock signal in the cycle 3. The register 33 outputs the logical OR value 36 (2) latched as a register value 37 (3) in the cycle 3, which is the next operation cycle.

The logical OR circuit 32 is a combinational circuit (asynchronous circuit). The logical OR circuit 32 outputs a logical OR between the seven bits excluding the sign bit (MSB) in the signal data (2) and the register value 37 (1) (zero) until a falling edge of the clock signal in the cycle 2 and outputs to the register 33 the logical OR between the seven bits excluding the sign bit (MSB) in the signal data (2) and the register value 37 (2) (the logical OR value 36 (1)) as the logical OR value 36 (2) when the register 33 outputs the register value 37 (2) (the logical OR value 36 (1)) on the falling edge of the clock signal in the cycle 2.

### (Cycles 3 to 8)

Likewise, the signal data (3) to (8) are supplied in the cycles 3 to 8. The logical OR circuit 32 that constitutes the maximum exponent calculation circuit 30 calculates a logical OR between seven bits excluding the sign bit (MSB) in each of the signal data (3) to (8) and each of the register value 37 (3) and register values 37 (4) to 37 (8) outputted by the register 33. The logical OR circuit 32 outputs the calculated logical ORs as logical OR values 36 (3) to 36 (8) to the register 33. Here, the register values 37 (3) to 37 (8) in the cycles 3 to 8 are the logical OR values 36 (2) to 36 (7) held in the cycles 2 to 7, respectively.
Logical OR value 36 (3): 0010111
Logical OR value 36 (4): 0011111
Logical OR value 36 (5): 0011111
Logical OR value 36 (6): 0011111
Logical OR value 36 (7): 0011111
Logical OR value 36 (8): 0011111

In the cycle 8, the block end signal BE becomes active (high level). The maximum exponent calculation circuit 30 receives the signal data (8), and the logical OR circuit 32 calculates the logical OR between the seven bits excluding the sign bit (MSB) in the signal data (8) and the register value 37 (8) outputted by the register 33. In the cycle 8, the logical OR circuit 32 outputs the logical OR between the seven bits excluding the sign bit (MSB) in the signal data (8) and the register value 37 (7) until a falling edge of the clock signal. Then, the logical OR circuit 32 outputs to the register 33 the logical OR between the seven bits excluding the sign bit (MSB) in the signal data (8) and the register value 37 (8) (the logical OR value 36 (7)) as the logical OR value 36 (8) when the register 33 outputs the register value 37 (8) (the logical OR value 36 (7)) on the falling edge of the clock signal in the cycle 8.

### (Cycle 9)

On a rising edge of the clock signal in the cycle 9, the register 33 captures the logical OR value 36 (8) outputted by the logical OR circuit 32 in the cycle 8. The register 33 outputs the logical OR value 36 (8) as a register value 37 (9) to the MSB-side bit position detection circuit 34 on a falling edge of the clock signal in the cycle 9. The cycle 9 is a cycle that follows the final operation cycle of the block.

In the cycle 9, the MSB-side bit position detection circuit 34 detects a bit position of a changed value on the MSB side of the bit string that constitutes the final logical OR value (8) of the block. The MSB-side bit position detection circuit 34 calculate s a maximum exponent from the detected bit position and outputs the calculated value as the maximum exponent 22. More specifically, since, counting the MSB as the zeroth bit, the second bit from the MSB in the logical OR value (8) has a value of one, then, according to the aforementioned formula (−1×M), the maximum exponent is −1×2=−2. Therefore, the MSB-side bit position detection circuit 34 outputs −2 as the maximum exponent 22.

In the cycle 9, which is a cycle that follows the final operation cycle of the block, the register 33 resets the logical OR value held for the block to the initial value of zero. As a result, the register 33 outputs the initial value of zero in a next cycle.

Here, the MSB-side bit position detection circuit 34 and the register 33 identify the final operation cycle of each block as a cycle in which the value of the supplied block end signal BE becomes 1.

In FIG. 10, the value of the block end signal BE being 1 in the cycle 8 indicates that the cycle 8 is the final operation cycle of the block.

The following describes an operation of normalization processing in the cycle 9 and cycles 10 to 16 with reference to FIG. 11.

In the cycles 1 to 8, the storage circuit 14 holds the signal data (1) to (8) while the maximum exponent calculation circuit 30 that constitutes the normalization circuit 20 calculates the maximum exponent.

Next, in the cycles 9 to 16 after the maximum exponent calculation circuit 30 calculated the maximum exponent in the cycle 9, the storage circuit 14 outputs the input data held therein as the signal data 23. Here, the storage circuit 14 may perform data reordering processing required in the signal processing apparatus 10. For instance, as an example of data reordering processing, the signal data, received in a sequential order from the signal data (1) to (8), may be rearranged, for instance, to an order of the signal data (1), (5), (2), (6), (3), (7), (4), and (8) and then outputted as the signal data 23.

The following describes a case where data reordering processing is not performed and the input data are outputted in the same order as they were received.

In the normalization circuit 20, the maximum exponent calculation circuit 30 calculates the maximum exponent in the cycles 1 to 8. Then, in the cycle 9, the maximum exponent calculation circuit 30 outputs −2 as the calculated maximum exponent (the maximum exponent 22) to the shift circuit 29. The maximum exponent calculation circuit 30 latches and outputs the maximum exponent of −2 until the cycle 16 when the storage circuit 14 outputs all pieces of the input data held therein.

Here, the maximum exponent calculation circuit 30 refers to the block end signal and identifies a timing for terminating the output of the maximum exponent. More specifically, the maximum exponent calculation circuit 30 terminates the output of the maximum exponent in the cycle 16 when the value of the block end signal becomes one again.

In the cycles 9 to 16, the shift circuit 29 performs normalization processing by sequentially and arithmetically shifting the signal data 23 (1) to 23 (8) outputted by the storage circuit 14 based on the maximum exponent of −2 calculated and outputted by the maximum exponent calculation circuit 30. Then, the shift circuit 29 outputs the data obtained by shifting the signal data 23 (1) to 23 (8) as normalized data 25 (1) to 25 (8). The shift circuit 29 may be constituted by a barrel shifter that (arithmetically) shifts an arbitrary bit length at a time. The barrel shifter (arithmetically) shifts a plurality of bits in a single clock cycle.

When the maximum exponent outputted from the maximum exponent calculation circuit 30 is −m (m is an integer equal to or greater than zero), the shift circuit 29 performs normalization by arithmetically shifting the signal data 23 (1) to 23 (8) to the left by m bits.

As a result, the normalized data 25 (1) to 25 (8) outputted by the shift circuit 29 have the following values, and the normalization processing is completed correctly. The data obtained by normalizing the signal data 23 (k) is shown as the normalized data 25 (k) (k is a positive integer from one to eight).
Normalized data 25 (1): 00011100
Normalized data 25 (2): 01000100
Normalized data 25 (3): 00011000
Normalized data 25 (4): 10101100
Normalized data 25 (5): 10000000
Normalized data 25 (6): 00011000
Normalized data 25 (7): 11001100
Normalized data 25 (8): 01101100

The correction circuit 21 refers to the maximum exponent 22 and corrects the normalized data 25 in the partial sign magnitude--representation normalized by the normalization circuit 20 so that the number N of unconverted bits is the same as before the normalization processing.

The number N of unconverted bits in the signal data 24 before the normalization processing is three (N=3). The number N of unconverted bits in the normalized data after the normalization processing, however, is changed to five (N=5) as a result of the 2-bits left shift in the normalization processing.

The correction circuit 21 corrects N to three (N=3), the same as before the normalization processing, by converting only the fourth and the fifth bits from the least significant bit (LSB) back to the sign magnitude—representation.

In the correction circuit 21, the decoder circuit 42 refers to the maximum exponent value of −2, which the normalization circuit 20 outputs as the maximum exponent 22, and outputs a value of 0011 (in binary) to the selection signal 41 so as to select and convert only the fourth and the fifth bits from the most significant bit (MSB). Here, the value of 0011 is a control signal value that controls the selective conversion circuits 40 for the second and the third bits from the most significant bit (MSB) not to convert the corresponding bits thereof and controls the selective conversion circuits 40 for the fourth and the fifth bits from the most significant bit (MSB) to convert the corresponding bits thereof.

More specifically, in the cycles 9 to 16, the correction circuit 21 corrects the normalized data 25 (1) to 25 (8) outputted by the normalization circuit 20 and outputs results as corrected data 26 (1) to 26 (8):
Corrected data 26 (1): 00011100
Corrected data 26 (2): 01000100
Corrected data 26 (3): 00011000
Corrected data 26 (4): 10110100
Corrected data 26 (5): 10011000
Corrected data 26 (6): 00011000
Corrected data 26 (7): 11010100
Corrected data 26 (8): 01101100

In the normalized data 25 (4), 25 (5), and 25 (7), the fourth and the fifth bits from the MSB are inverted by the selection signal 41.

Next, the conversion circuit 13b performs conversion processing corresponding to the number N(=3) of unconverted bits. More specifically, in the cycles 9 to 16, the conversion circuit 13b converts the corrected data 26 (1) to 26 (8) represented in the partial sign magnitude--representation to the two's complement representation and outputs results as output data (1) to (8):
Output data (1): 00011100
Output data (2): 01000100
Output data (3): 00011000
Output data (4): 11001100
Output data (5): 11100000
Output data (6): 00011000
Output data (7): 10101100
Output data (8): 01101100

In the output data (4), (5), and (7), the N(=3) consecutive lower bits including the LSB in the corrected data are unconverted, and each of the (D−N−1) (=4) bits immediately above these lower bits are inverted from the corrected data.

As described above, according to an example of the signal processing apparatus 10 of the present disclosure, the storage processing parts 11a, 11b, and 11c convert data represented in the two's complement representation to data in the partial sign magnitude--representation, perform storage processing thereon, and then convert the data back to the two's complement representation. As illustrated in FIG. 3, with a value zero as a boundary, the difference in bit values between positive and negative values is small in the partial sign magnitude—representation, as in the sign magnitude representation. Hence, when a signal with a value that frequently changes between positive and negative in the vicinity of zero is represented in the partial sign magnitude—representation, the bit-wise operation rate is small. As a result, the percentage-activity of the storage processing parts 11a, 11b, and 11c can be reduced, compared with a case where the processing takes place without converting the two's complement representation. The conversion circuit 13 performs conversion between the two's complement representation and the partial sign magnitude--representation only with bit inversion processing and does not require add-one processing (increment processing), which is required when using the sign magnitude representation. Bit inversion can be achieved only with an XOR circuit. Therefore, this can be implemented with an overwhelmingly small circuit scale, as compared with other logic processing circuits and operation processing circuits. As compared with conversion between the two's complement representation and the sign magnitude--representation, the number of required XOR circuits 17 is smaller, and the scale of the conversion circuit 13 can be reduced accordingly.

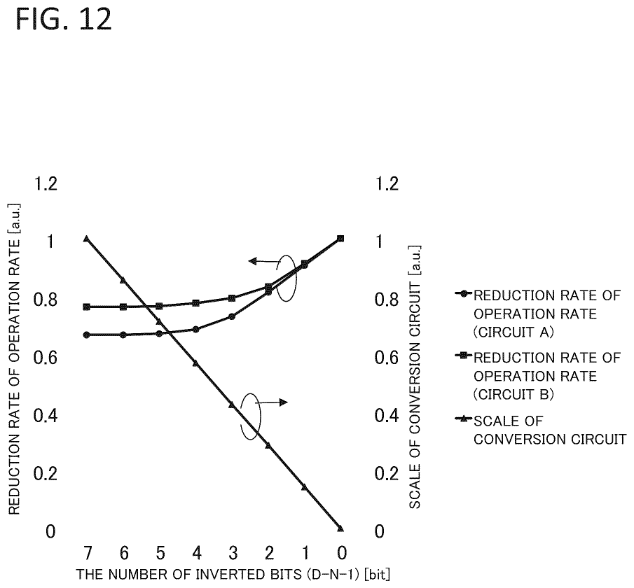

FIG. 12 is a diagram schematically illustrating an effect(s) of the present disclosure using a graph. In FIG. 12, a graph illustrates effects of the partial sign magnitude--representation applied to two example circuits, a circuit A and a circuit B, as a storage processing part in an FFT processing circuit, in which the bit width of signal data is eight bits (D=8). The horizontal axis in FIG. 12 is the number of inverted bits (D−N−1) in conversion between the two's complement representation and the partial sign magnitude—representation. When the number of inverted bits is zero, there is no inverted bit, and the partial sign magnitude--representation is the same as the two's complement representation. When the number of inverted bits is seven, since all the bits except for the sign bit are bit-wise inverted, this is the same as the sign magnitude—representation. A case where the number of inverted bits is one to six corresponds to the partial sign magnitude--representation. The left vertical axis is a reduction rate of the bit-wise operation rate which indicates a relative value based on the operation rate in the two's complement representation. The right vertical axis is a scale of the conversion circuit which indicates a relative value based on the scale of the conversion circuit in the sign magnitude--representation.

With reference to FIG. 12, for instance, in a case where the number of inverted bits is four, the bit-wise operation rates of the circuits A and B in the partial sign magnitude--representation are reduced to 20 to 30 percent of those in a case where the two's complement representation is used. This is the same reduction rate as when the sign magnitude--representation is used. The circuit scale is reduced to 40 percent as compared with a case where the sign magnitude--representation is used. That is, according to the present example embodiment, with a conversion circuit smaller than that in the sign magnitude--representation, the bit-wise operation rate can be reduced to the same extent as the sign magnitude--representation. In several example embodiments of the present disclosure, even when processing a signal with a value which frequently changes between positive and negative in the vicinity of zero, it is possible to keep the operation rate in the storage processing parts 11a, 11b, and 11c small. As a result, the power dissipation in the storage processing parts 11a, 11b, and 11c can be reduced.

The operation processing parts 12a and 12b perform operation processing in the two's complement representation. Therefore, the percentage-activity related to operation processing is not reduced. However, unlike in the case where the sign magnitude representation is applied, the circuit scale does not increase because a conversion circuit (including an add-one circuit) for conversion between the two's complement representation and other data representation formats is not included. Therefore, the power dissipation of the entire signal processing apparatus can be reduced by a reduction amount of power dissipation in the storage processing parts 11a, 11b, and 11c.

In the present disclosure described above, although the storage processing parts 11a, 11b, and 11c perform storage processing such as buffering, re-timing, and rearranging signal data in the partial sign magnitude—representation and the operation processing parts 12a and 12b perform operation processing such as addition/subtraction and multiplication/division in the two's complement representation, the storage processing parts 11a, 11b, and 11c may perform operation processing such as addition/subtraction and multiplication/division based on the partial sign magnitude--representation if a desired result can be obtained from the processing in the partial sign magnitude--representation, in addition to the storage processing.

The correction circuit 21 corrects the signal data 24 in the partial sign magnitude--representation, in which the number N of unconverted bits is changed by the normalization circuit 20, so that the number N of unconverted bits is the same as that in the partial sign magnitude--representation before the normalization processing. Therefore, even in a case where the number N of unconverted bits is changed by normalization processing performed by the normalization circuit 20, the partial sign magnitude--representation can be converted back to the two's complement representation. As a result, according to the present example embodiment, it is possible to perform normalization processing on signal data represented in the partial sign magnitude--representation.

Normalization is to be performed either within a part that uses the two's complement representation, or after converted to the two's complement representation when a different representation format is used. This means that one may not be able to perform normalization at an appropriate stage, or numerous circuits may be required for conversion to the two's complement representation. As a result, problems such as an increased circuit scale and higher power dissipation occur. In contrast, according to the example embodiments, a normalization process can be performed at an appropriate stage without conversion to the two's complement representation, which makes it possible to reduce circuit scale and power dissipation.

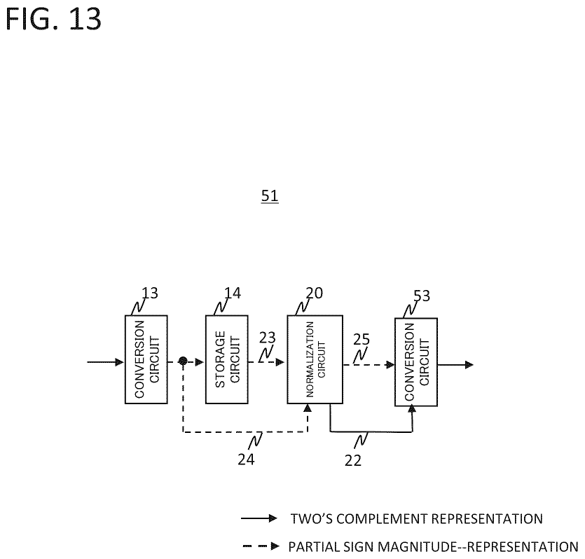

The following describes another example of several example embodiments of the present disclosure. FIG. 13 is a diagram illustrating a configuration example of a storage processing part 51. The storage processing part 51 includes a conversion circuit 13, a storage circuit 14, a normalization circuit 20, and a conversion circuit 53. The conversion circuit 13, the storage circuit 14, and the normalization circuit 20 are configured identically to each corresponding circuit constituting the storage processing part 11 of FIG. 2 and are given the same reference signs. The conversion circuit 53 is configured differently from the conversion circuit 13 of FIG. 4; it refers to a maximum exponent 22 to perform conversion processing.

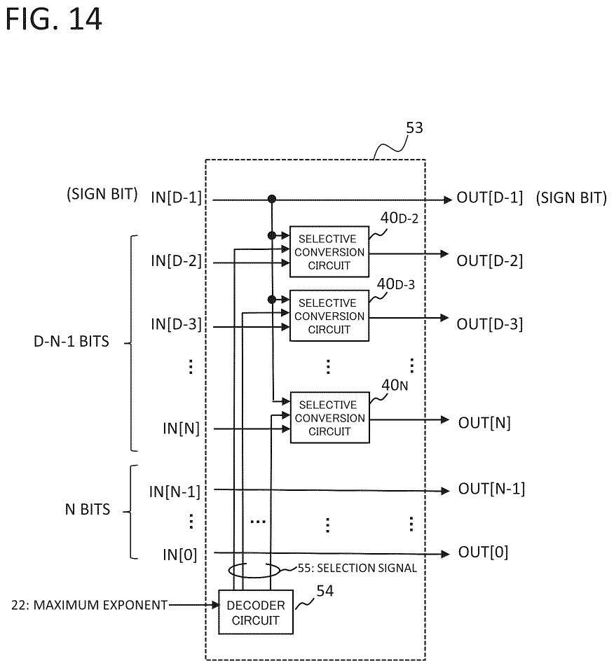

FIG. 14 is a diagram illustrating a configuration example of the conversion circuit 53. With reference to FIG. 14, the conversion circuit 53 receives the most significant bit indicating a sign from an input IN[D−1] and outputs as it is to OUT[D−1] as a sign bit. The conversion circuit 53 outputs N consecutive lower bits including the least significant bit received from inputs IN[0] to IN[N−1], as they are, to outputs OUT[0] to OUT[N−1], respectively.

Based on a selection signal 55, selective conversion circuits 40_{N} to 40_{D-2} choose whether to output remaining (D−N−1) bits received from inputs IN[N] to IN[D−2] as they are, respectively, or perform bit inversion processing thereon through an XOR operation between the most significant bit indicating a sign received from the input IN[D−1] and each of the (D−N−1) bits and then output them to outputs OUT[N] to OUT[D−2], respectively.

A decoder circuit 54 refers to the maximum exponent 22 outputted by the normalization circuit 20 and outputs the selection signal 55 that corrects represented bit position(s) in the supplied signal data to that/those before normalization processing by controlling each of the plurality of selective conversion circuits 40 either to output the input as it is without conversion, or to perform bit inversion processing on the input using an XOR operation with the most significant bit indicating a sign, supplied from the input IN[D−1], and output resultant data.

More specifically, the decoder circuit 54 controls the selective conversion circuits 40 not to convert N consecutive lower bits including the least significant bit (LSB). (D−N−1) bits between the most significant bit (MSB), which is a sign bit, and the N consecutive lower bits are converted by the selective conversion circuits 40_{N} to 40_{D-2}, respectively. As a result, the conversion circuit 53 is enabled to directly convert signal data represented in the partial sign magnitude—representation having the number N of unconverted bits changed by normalization processing to the two's complement representation.

The following describes an example of an operation of the storage processing part 51. In the storage processing part 51, the conversion circuit 13, the storage circuit 14, and the normalization circuit 20 are configured identically to each corresponding circuit constituting the storage processing part 11 relating to the first example embodiment and operate in the same manner. More specifically, since the storage processing part 51 performs the same operation as that of the storage processing part 11 in the cycles 1 to 9 described with reference to FIG. 10, an operation of the storage processing part 51 in the cycles 1 to 9 is not described.

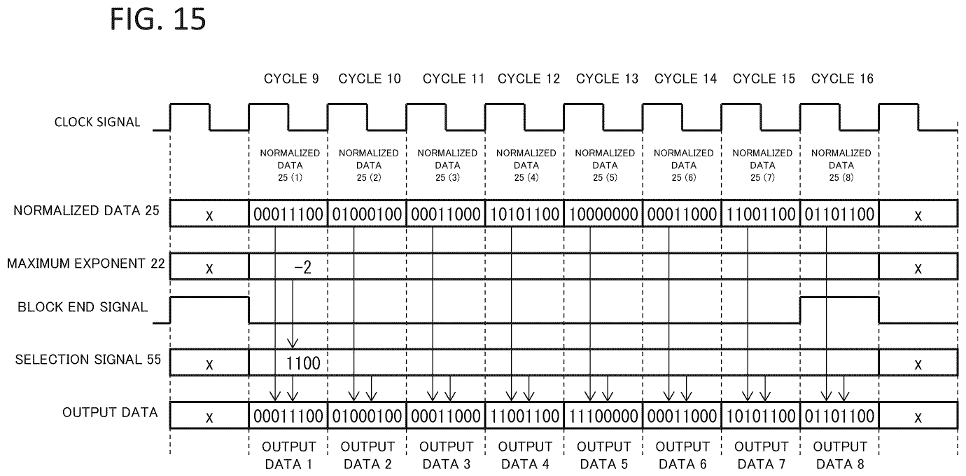

With reference to FIG. 15, the following describes an operation of the conversion circuit 53 in the cycles 9 to 16. The normalization circuit 20 also operates identically to the normalization circuit 20 of the storage processing part 11 relating to the first example embodiment in the cycles 9 to 16. More specifically, values of normalized data 25 (1) to 25 (8) outputted by the normalization circuit 20 in the cycles 9 to 16 are as follows:
Normalized data 25 (1): 00011100
Normalized data 25 (2): 01000100
Normalized data 25 (3): 00011000
Normalized data 25 (4): 10101100
Normalized data 25 (5): 10000000
Normalized data 25 (6): 00011000
Normalized data 25 (7): 11001100
Normalized data 25 (8): 01101100

The conversion circuit 53 refers to the maximum exponent 22 and converts the normalized data 25 in the partial sign magnitude--representation normalized by the normalization circuit 20 to output data represented in the two's complement representation. The number N of unconverted bits in the normalized data 25 after the normalization processing is changed to five (N=5) as a result of a 2-bits left shift in the normalization processing. The conversion circuit 53 correctly converts the data to the two's complement representation by inverting only the second and the third bits from the most significant bit through an XOR operation with the most significant bit.

In the conversion circuit 53, the decoder circuit 54 refers to a maximum exponent value of −2, which the normalization circuit 20 outputs as the maximum exponent 22, and outputs a value of 1100 (in binary) to the selection signal 55 so as to select and convert only the second and the third bits from the most significant bit (MSB). Here, the value of 1100 is a control signal value that controls the selective conversion circuits 40₆ and 40₅ (40_{D-2} and 40_{D-3} in FIG. 14; D=8) for the second and the third bits from the most significant bit to convert the corresponding bits thereof and controls the selective conversion circuits 40₄ and 40₃ (40_{D-4} and 40_{D-5} in FIG. 14; D=8) for the fourth and the fifth bits from the most significant bit (MSB) not to convert the corresponding bits thereof. More specifically, in the cycles 9 to 16, the conversion circuit 53 converts the normalized data 25 (1) to 25 (8) outputted by the normalization circuit 20 to the two's complement representation and outputs results as output data (1) to (8):
Output data (1): 00011100
Output data (2): 01000100
Output data (3): 00011000
Output data (4): 11001100
Output data (5): 11100000
Output data (6): 00011000
Output data (7): 10101100
Output data (8): 01101100

In the configuration of FIG. 2, for instance, for the eight-bits normalized data (7) of 11001100 (D=8; three unconverted bits (N=3)), when the maximum exponent is −2, the correction circuit 21 (FIG. 8) outputs the corrected data (7) of 11010100 obtained by having the four-bits selection signal 41 (0011) from the decoder circuit 42 control the selective conversion circuits 40 (3) and 40 (4) to invert the bits from IN[3] and IN[4] and the selective conversion circuits 40 (5) and 40 (6) to leave the bits from IN[5] and IN[6] alone, and the conversion circuit 13b (FIG. 4) outputs from OUT[7:0] the output data 10101100 obtained by inverting the bits from IN[3] to IN[6]. Meanwhile, the conversion circuit 53 outputs from OUT[7:0] the output data (7) 10101100 obtained by having the four-bits selection signal 55 (1100) from the decoder circuit 54 control the selective conversion circuits 40 (5) and 40 (6) to invert the bits from IN[5] and IN[6] and the selective conversion circuits 40 (3) and 40 (4) to leave the bits from IN[3] and IN[4] alone.

As described, even when processing a signal with a value which frequently changes between positive and negative in the vicinity of zero in the partial sign magnitude--representation, it is possible to keep the percentage-activity in the storage processing part 51 to a minimum in this example as well. As a result, the power dissipation in the storage processing part 51 can be reduced.

Further, by referring to the maximum exponent 22, the conversion circuit 53 can convert the signal data 24 in the partial sign magnitude--representation, in which the number N of unconverted bits is changed by the normalization circuit 20, directly to the two s complement representation. As a result, it is possible to normalize signal data represented in the partial sign magnitude--representation. Therefore, normalization processing can be performed at an appropriate stage without conversion to the two's complement representation. As a result, a circuit scale and a power dissipation can be reduced. Further, the correction circuit 21 of FIG. 2 is not required, allowing for a corresponding reduction in circuit scale and power dissipation.

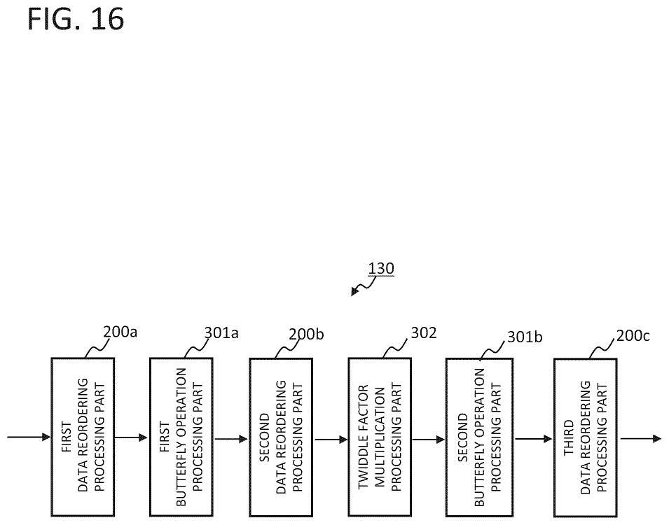

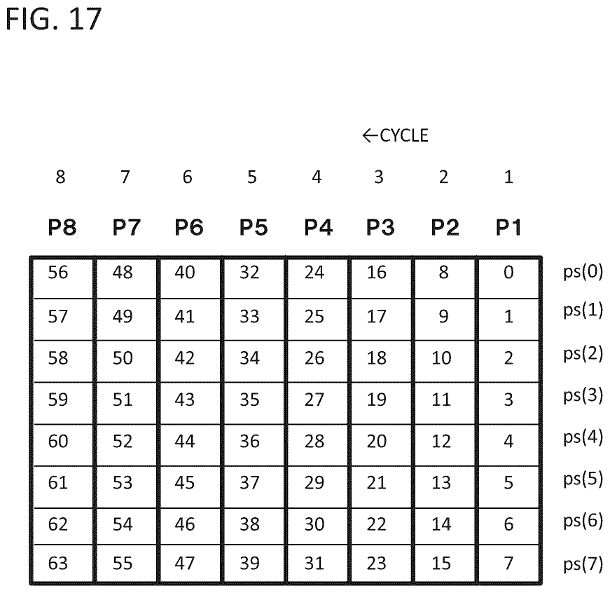

FIG. 16 is a diagram schematically illustrating an example of an FFT apparatus 130 relating to an example embodiment of the present disclosure. The FFT apparatus 130 processes 64-point FFT decomposed into two-stages of radix-8 butterfly processing, using a pipeline circuit scheme, according to the data flow 500 illustrated in FIG. 21. The FFT apparatus 130 receives time-domain data x(n) (n=0, 1, . . . , N−1), performs Fourier-transformation on x(n) using FFT processing, and generates and outputs frequency-domain signals X(k) (k=0, 1, . . . , N−1). Here, N is a positive integer representing a FFT block size. It is assumed that the FFT apparatus 130 performs a 64-point FFT process in 8-data parallel (N=64), as a non-limiting example. In this case, the FFT apparatus 130 receives the time-domain data x(n) and generates and outputs the frequency-domain signals X(k), which have been Fourier-transformed using FFT processing. 64 pieces of data in total, eight pieces at a time in eight cycles, are inputted as the input data x(n) in the order as illustrated in FIG. 17. The numbers from 0 to 63 (eight rows×eight columns of elements) shown in a table in FIG. 17 represent an index n of x(n).

More specifically, in the first cycle, eight pieces of data x(0), x(1), . . . , and x(7) constituting a data set P1 are inputted.

Then, eight pieces of data x(8), x(9), . . . , and x(15) constituting a data set P2 are inputted in the second cycle. Similarly, in each cycle from the third to the eighth, data constituting data sets P3 to P8 are inputted thereafter, respectively.

Likewise, 64 pieces of data, eight pieces of data at a time in eight cycles, are outputted as output data X(k) in the order illustrated in FIG. 10. Note that the numbers from 0 to 63 shown in the table in FIG. 10 represent an index k of X(k).

More specifically, in the first cycle, eight pieces of data x(0), x(1), . . . , and x(7) constituting the data set P1 are outputted.

Eight pieces of data x(8), x(9), . . . , and x(15) constituting the data set P2 are outputted in the second cycle. Similarly, in each cycle from the third to the eighth, data constituting the data sets P3 to P8 are outputted thereafter, respectively.

As illustrated in FIG. 16, the FFT apparatus 130 includes a first data reordering processing part 200a, a first butterfly operation processing part 301a, a second data reordering processing part 200b, a twiddle factor multiplication processing part 302, a second butterfly operation processing part 301b, and a third data reordering processing part 200c.

The FFT apparatus 130 performs first data reordering processing, first butterfly operation processing, second data reordering processing, twiddle factor multiplication processing, second butterfly operation processing, and third data reordering processing, in pipeline processing.

The first data reordering processing part 200a and the second data reordering processing part 200b include buffer circuits to rearrange data. The first data reordering processing part 200a and the second data reordering processing part 200b rearrange a data sequence before and after the first butterfly operation processing part 32a, respectively, based on data dependency in an FFT processing algorithm.

Likewise, the third data reordering processing part 200c is a buffer circuit to rearrange data. That is, the third data reordering processing part 200c rearranges a data sequence after the second butterfly operation processing part 32b based on the data dependency in the algorithm of the FFT processing.

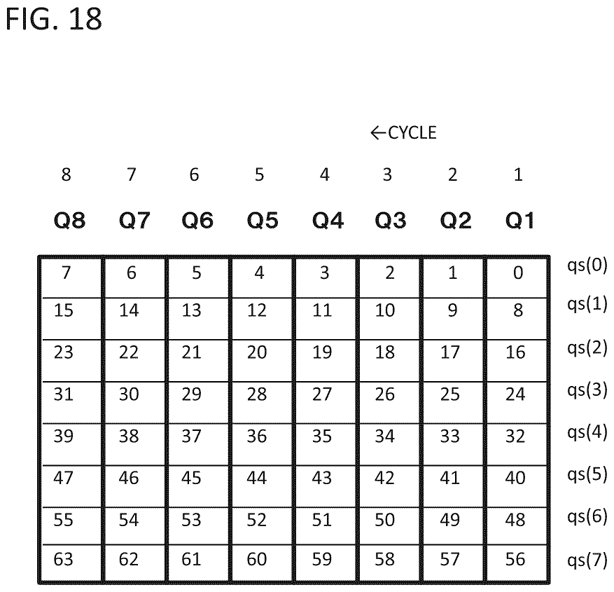

More specifically, the first data reordering processing part 200a rearranges a “sequential order” as illustrated in FIG. 17, which is an input order of the input data x(n), to a “bit-reversed order” as illustrated in FIG. 18, which corresponds to an order with which data is supplied to the first butterfly operation processing part 301a.

The bit-reversed order illustrated in FIG. 18 corresponds to input data sets supplied to the radix-8 butterfly operation processing part 502 in the first stage in the data flow diagram illustrated in FIG. 21.

More specifically, in a first cycle, eight pieces of data x(0), x(8), . . . , and x(56) constituting a data set Q1 are inputted. Then, eight pieces of data x(1), x(9), and x(57) constituting a data set Q2 are inputted in a second cycle. Similarly, in each cycle from a third to an eighth, data constituting data sets Q3 to Q8 are inputted thereafter, respectively.

A sequential order is an order of eight data sets P1, P2, P3, P4, P5, P6, P7, and P8 as illustrated in FIG. 17. A data set Ps (where s is a value representing an order of a processing cycle; s=1, 2, . . . , 8) is constituted by eight pieces of data sequentially arranged from ps(0) to ps(7).

Assuming that x(0) to x(63), 64 pieces of data in total, every eight pieces in each cycle (total, eight cycles), are inputted in parallel in the order illustrated in FIG. 17, ps(i) (s, i=0, . . . , 7) is given as follows:

$$ps ( i ) = x [ 8 \times ( s - 1 ) + i ]$$

The data sets are arranged in the order of P1, P2, P3, P4, P5, P6, P7, and P8 corresponding to the progress of the processing cycles. In the sequential order, s sets of data, in which i*s pieces of data are arranged from the first data to the last, by every i pieces of data, in the order of data are arranged in the order of cycles.

A bit-reversed order is an order of the eight data sets Q1, Q2, Q3, Q4, Q5, Q6, Q7, and Q8 illustrated in FIG. 18. A data set Qs (where s is a value representing an order of a processing cycle; s=1, 2, . . . , 8) is constituted by eight pieces of data sequentially arranged from qs(0) to qs(7). For 64 pieces of data x(0) to x(63) supplied in the sequential order, qs(i) (s, i=0, . . . , 7) is given as follows:

$$qs ( i ) = x [ ( s - 1 ) + 8 \times i ]$$

The data sets are arranged in the order of Q1, Q2, Q3, Q4, Q5, Q6, Q7, and Q8 corresponding to the progress of the processing cycles. In the bit-reversed order, s pieces out of i*s pieces of data supplied in the sequential order are arranged from the first piece in the order of cycles, and i pieces of data in the same cycle are sequentially arranged as a set.

Each data set in the bit-reversed order is uniquely determined in a case where each data set in the sequential order is configured. The i-th data Qs(i) (i=0, . . . , 7) out of data constituting each data set Qs (s=1, . . . , 8) in the bit-reversed order is the (s−1)-th piece of data Pᵢ₊₁ (s−1) in the (i+1)-th cycle according to the sequential order. That is,

$$Qs ( i ) = {P}_{i + 1} ( s - 1 )$$

Here, if the i-th data in Ps and Qs (s=1, . . . , 8) are represented by Ps(i) and Qs(i) (i=1, . . . , 8), the above equation is expressed as:

$$Qs ( i ) = Pi ( s )$$

That is, Qs(i) and Pi(s) have a relationship in which the progress order of cycles is replaced by the order of data positions with respect to pieces of data constituting each data set. Hence, if pieces of data supplied in the bit-reversed order are rearranged according to the bit-reversed order, they will form a sequence in the sequential order.

Each row pₛ(i) in FIG. 17 and eight rows qₛ(i) in FIG. 18 represent the i-th data to be supplied in the subsequent stage. Each of eight numerals included in each data set is an identifier specifying an FFT point and is specifically the index n in x(n).

The sequential order and the bit-reversed order are, as a matter of course, not limited to those illustrated in FIGS. 17 and 18. Each data set in the sequential order can be created by sequentially arranging data according to the number of FFT points, the number of cycles, and the number of data processed in parallel, as described above. Each data set in the bit-reversed order can be created by replacing the order of cycle progression with the order of data position, for data supplied in the sequential order, as described above.

The first butterfly operation processing part 301a performs the first butterfly operation processing (the first butterfly operation process) of the radix-8 butterfly operation processing performed twice in the data flow 500 illustrated in FIG. 21.

The first butterfly operation processing part 301a outputs the results of the butterfly operation in the sequential order as illustrated in FIG. 17 as data y(n) (n=0, 1, . . . , 63).

The second data reordering processing part 200b rearranges the data y(n) outputted in the sequential order by the first butterfly operation processing part 301a to the bit-reversed order as illustrated in FIG. 18 in order to supply the data to the second butterfly operation processing part 301b.

The twiddle factor multiplication processing part 302 applies complex rotation on a complex plane of the FFT operation after the first butterfly operation, which corresponds to the twiddle factor multiplication processing part 504 in the data flow 500 illustrated in FIG. 21. Data rearrangement is not performed in the twiddle factor multiplication process.

The second butterfly operation processing part 301b, which corresponds to a butterfly operation processing circuit, performs the second butterfly operation processing by the radix-8 butterfly operation processing part 503 in the data flow diagram illustrated in FIG. 21. The second butterfly operation processing part 301b performs butterfly operation processing on data y′(n) (n=0, 1, . . . , 63) supplied in the bit-reversed order after the twiddle factor multiplication and outputs the results X(k) (k=0, 1, . . . , 63), also in the bit-reversed order.

The third data reordering processing part 200c rearranges the data X(k) outputted in the bit-reversed order by the second butterfly operation processing part 301b to the sequential order illustrated in FIG. 17.

A data reordering processing part 200 realizes data reordering processing according to the sequential order illustrated in FIG. 17 and the bit-reversed order illustrated in FIG. 18 by temporarily storing received data and controlling selection and output of the stored data. The following describes a concrete example of the data reordering processing part 200.

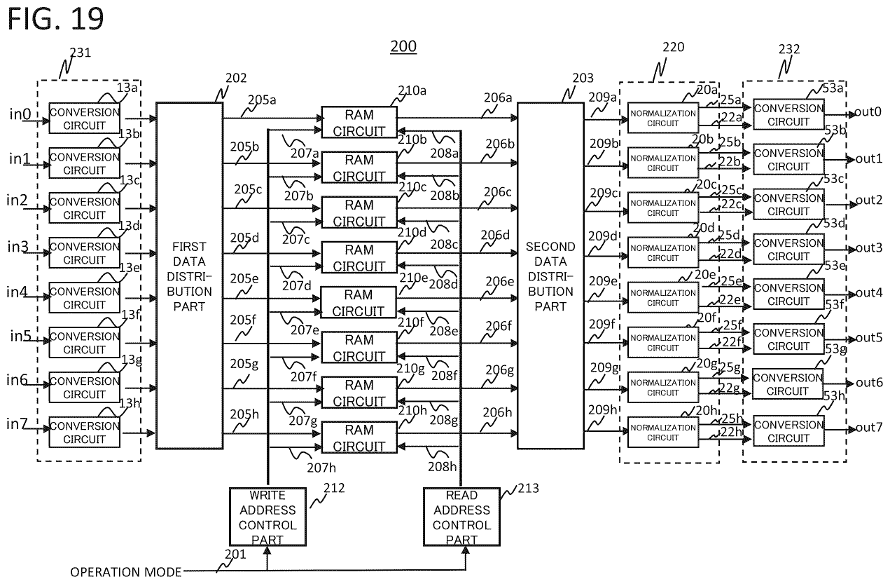

With reference to FIG. 19, the data reordering processing part 200 includes a first conversion circuit 231, a first data distribution part 202, eight RAM (Random Access Memory) circuits 210a, 210b, 210c, 210d, 210e, 210f, 210g, and 210h, a second data distribution part 203, a write address control part 212, a read address control part 213, a normalization circuit 220, and a second conversion circuit 232.

The first conversion circuit 231 simultaneously receives (in parallel) eight pieces of data (D-bits data in the two's complement representation) supplied from eight inputs in0 to in7 in the sequential order illustrated in FIG. 17 and converts the data in two's complement representation to those in the partial sign magnitude—representation.

The first conversion circuit 231 is constituted by eight conversion circuits 13a to 13h corresponding to the eight inputs in0 to in7. Each of the conversion circuits 13a to 13h is identical to the conversion circuit 13 of FIG. 4. The conversion circuits 13a to 13h convert the data in two's complement representation, supplied to each input in parallel, to those in the partial sign magnitude--representation. More specifically, the conversion circuits convert the data to those in the partial sign magnitude--representation by inverting (D-N−1) bits in the supplied D-bits data, excluding the most significant bit and the N least significant bits, when the most significant bit indicating a sign is one.

The first data distribution part 202 performs data distribution processing on the eight pieces of data converted to the partial sign magnitude--representation by the first conversion circuit 231 and outputs the results to eight outputs (data lines) 205a to 205h.

Each of the eight RAM circuits 210a to 210h is a RAM circuit enabled to store eight pieces of data. Therefore, the RAM circuits 210a to 210h are enabled to store a total of 64 pieces of data (8×8:8 in parallel, depth 8), which is equal to the number of points in a 64-point FFT. Each of the RAM circuits 210a to 210h may be a dual-port RAM circuit that includes independent write and read ports and prioritizes reading when both writing and reading occur at the same address simultaneously. That is, after reading data stored at a target address for writing and reading, the RAM circuit writes data to be written. The RAM circuits 210a to 210h may be constituted by dual-port SRAMs (Static Random Access Memory) and DRAMs (Dynamic Random Access Memory). In the RAM circuits 210a to 210h, control terminals such as chip enable (CE), output enable (OE), and write enable (WE), and control signals supplied to these control terminals are omitted.

The RAM circuit 210a stores the data outputted by the first data distribution part 202 to the data line (D bit) 205a at an address outputted by the write address control part 212 to an address line 207a, reads the stored data using an address outputted by the read address control part 213 to an address line 208a, and outputs the result to a data line 206a.

Likewise, the RAM circuit 210b stores the data outputted by the first data distribution part 202 to the data line 205b at an address outputted by the write address control part 212 to an address line 207b, reads the stored data using an address outputted by the read address control part 213 to an address line 208b, and outputs the result to a data line 206b.

The RAM circuit 210c stores the data outputted by the first data distribution part 202 to the data line 205c at an address outputted by the write address control part 212 to an address line 207c, reads the stored data using an address outputted by the read address control part 213 to an address line 208c, and outputs the result to a data line 206c.

The RAM circuit 210d stores the data outputted by the first data distribution part 202 to the data line 205d at an address outputted by the write address control part 212 to an address line 207d, reads the stored data using an address outputted by the read address control part 213 to an address line 208d, and outputs the result to a data line 206d.

The RAM circuit 210e stores the data outputted by the first data distribution part 202 to the data line 205e at an address outputted by the write address control part 212 to an address line 207e, reads the stored data using an address outputted by the read address control part 213 to an address line 208e, and outputs the result to a data line 206e.

The RAM circuit 210f stores the data outputted by the first data distribution part 202 to the data line 205f at an address outputted by the write address control part 212 to an address line 207f, reads the stored data using an address outputted by the read address control part 213 to an address line 208f, and outputs the result to a data line 206f.

The RAM circuit 210g stores the data outputted by the first data distribution part 202 to the data line 205g at an address outputted by the write address control part 212 to an address line 207g, reads the stored data using an address outputted by the read address control part 213 to an address line 208g, and outputs the result to a data line 206g.

The RAM circuit 210h stores the data outputted by the first data distribution part 202 to the data line 205h at an address outputted by the write address control part 212 to an address line 207h, reads the stored data using an address outputted by the read address control part 213 to an address line 208h, and outputs the result to a data line 206h.

The second data distribution part 203 simultaneously receives eight pieces of data from the eight inputs (data lines) 206a to 206h, performs data distribution processing, and simultaneously outputs eight pieces of data from eight output data lines 209a to 209h to the normalization circuit 220. The normalization circuit 220 includes eight normalization circuits 20a to 20h (FIG. 5) corresponding to the eight output data lines 209a to 209h.

The eight normalization circuits 20a to 20h of the normalization circuit 220 each perform normalization on a block constituted by eight consecutive pieces of data and output normalized data 25a to 25h and maximum exponents 22a to 22h to eight conversion circuits 53a to 53h of the second conversion circuit 232, respectively.

Each of the conversion circuits 53a to 53h of the second conversion circuit 232 is configured as illustrated in FIG. 14. When the most significant bit of the supplied normalized data (D bits), represented in the two's complement representation, is one (in a case of negative data), for (D−N−1) bits between the most significant bit and N consecutive lower bits including the least significant bit of the normalized data, the conversion circuit 53 (53a to 53h) inverts bit(s) specified as one by a selection signal 55 obtained by decoding the maximum exponent 22 (22a to 22h) using a decoder circuit 54 and outputs the result.

The write address control part 212 refers to an operation mode 201 and outputs the addresses with which the RAM circuits 210a to 210h write data to the address lines 207a to 207h, respectively.

The read address control part 213 refers to the operation mode 201 and outputs the addresses with which the RAM circuits 210a to 210h read data to the address lines 208a to 208h, respectively.

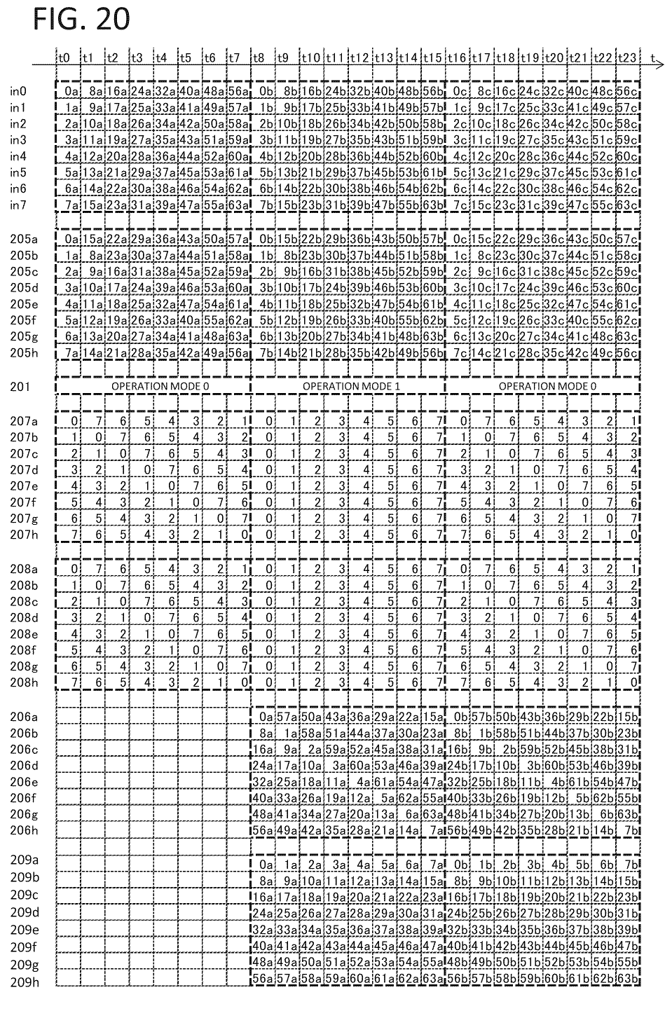

The following describes a specific operation of the data reordering processing part 200. FIG. 20 is a time chart showing an example of an operation of the data reordering processing part 200.

The data reordering processing part 200
receives 64 pieces of data 0a to 63a in 8-data parallel in the sequential order from the inputs in0 to in7 in eight cycles t0 to t7 and
outputs 64 pieces of data 0a to 63a in 8-data parallel in the bit-reversed order to outputs out0 to out7 in eight cycles t8 to t15.

Likewise, the data reordering processing part 200
receives 64 pieces of data 0b to 63b in 8-data parallel in the sequential order from the inputs in0 to in7 in the eight cycles t8 to t15 and
outputs 64 pieces of data 0b to 63b in 8-data parallel in the bit-reversed order to the outputs out0 to out7 in eight cycles t16 to t23.

The data reordering processing part 200
receives 64 pieces of data 0c to 63c in 8-data parallel in the sequential order from the inputs in0 to in7 in the eight cycles t16 to t23 and
outputs 64 pieces of data 0c to 63c in 8-data parallel in the bit-reversed order to the outputs out0 to out7 in eight cycles t24 to t31 (not shown in the drawing).

First, the following describes in detail how the data reordering processing part 200 receives the data 0a to 63a in the eight cycles t0 to t7.

In the cycle t0,

the first data distribution part 202
outputs to the data line 205a the data 0a received from in0 and converted by the first conversion circuit 231 (the conversion circuit 13a) from the two's complement representation to the partial sign magnitude—representation,
outputs to the data line 205b the data 1a received from in1 and converted by the first conversion circuit 231 (the conversion circuit 13b) from the two's complement representation to the partial sign magnitude—representation,
outputs to the data line 205c the data 2a received from in2 and converted by the first conversion circuit 231 (the conversion circuit 13c) from the two's complement representation to the partial sign magnitude—representation,
outputs to the data line 205d the data 3a received from in3 and converted by the first conversion circuit 231 (the conversion circuit 13d) from the two's complement representation to the partial sign magnitude—representation,
outputs to the data line 205e the data 4a received from in4 and converted by the first conversion circuit 231 (the conversion circuit 13e) from the two's complement representation to the partial sign magnitude—representation,
outputs to the data line 205f the data 5a received from in5 and converted by the first conversion circuit 231 (the conversion circuit 13f) from the two's complement representation to the partial sign magnitude—representation,
outputs to the data line 205g the data 6a received from in6 and converted by the first conversion circuit 231 (the conversion circuit 13g) from the two's complement representation to the partial sign magnitude—representation, and
outputs to the data line 205h the data 7a received from in7 and converted by the first conversion circuit 231 (the conversion circuit 13h) from the two's complement representation to the partial sign magnitude—representation.

In the cycle t1,

the first data distribution part 202
outputs to the data line 205b the data 8a received from in0 and converted by the first conversion circuit 231 (the conversion circuit 13a) from the two's complement representation to the partial sign magnitude—representation,
outputs to the data line 205c the data 9a received from in1 and converted by the first conversion circuit 231 (the conversion circuit 13b) from the two's complement representation to the partial sign magnitude—representation,
outputs to the data line 205d the data 10a received from in2 and converted by the first conversion circuit 231 (the conversion circuit 13c) from the two's complement representation to the partial sign magnitude—representation,
outputs to the data line 205e the data 11a received from in3 and converted by the first conversion circuit 231 (the conversion circuit 13d) from the two's complement representation to the partial sign magnitude—representation,
outputs to the data line 205f the data 12a received from in4 and converted by the first conversion circuit 231 (the conversion circuit 13e) from the two's complement representation to the partial sign magnitude—representation,
outputs to the data line 205g the data 13a received from in5 and converted by the first conversion circuit 231 (the conversion circuit 13f) from the two's complement representation to the partial sign magnitude—representation,
outputs to the data line 205h the data 14a received from in6 and converted by the first conversion circuit 231 (the conversion circuit 13g) from the two's complement representation to the partial sign magnitude—representation, and
outputs to the data line 205a the data 15a received from in7 and converted by the first conversion circuit 231 (the conversion circuit 13h) from the two's complement representation to the partial sign magnitude—representation.

In the cycle t2,

the first data distribution part 202
outputs to the data line 205c the data 16a received from in0 and converted by the first conversion circuit 231 (the conversion circuit 13a) from the two's complement representation to the partial sign magnitude—representation,
outputs to the data line 205d the data 17a received from in1 and converted by the first conversion circuit 231 (the conversion circuit 13b) from the two's complement representation to the partial sign magnitude—representation,
outputs to the data line 205e the data 18a received from in2 and converted by the first conversion circuit 231 (the conversion circuit 13c) from the two's complement representation to the partial sign magnitude—representation,
outputs to the data line 205f the data 19a received from in3 and converted by the first conversion circuit 231 (the conversion circuit 13d) from the two's complement representation to the partial sign magnitude—representation,
outputs to the data line 205g the data 20a received from in4 and converted by the first conversion circuit 231 (the conversion circuit 13e) from the two's complement representation to the partial sign magnitude—representation,
outputs to the data line 205h the data 21a received from in5 and converted by the first conversion circuit 231 (the conversion circuit 13f) from the two's complement representation to the partial sign magnitude—representation,
outputs to the data line 205a the data 22a received from in6 and converted by the first conversion circuit 231 (the conversion circuit 13g) from the two's complement representation to the partial sign magnitude—representation, and
outputs to the data line 205b the data 23a received from in7 and converted by the first conversion circuit 231 (the conversion circuit 13h) from the two's complement representation to the partial sign magnitude—representation.

In the cycle t3,

the first data distribution part 202
outputs to the data line 205d the data 24a received from in0 and converted by the first conversion circuit 231 (the conversion circuit 13a) from the two's complement representation to the partial sign magnitude—representation,
outputs to the data line 205e the data 25a received from in1 and converted by the first conversion circuit 231 (the conversion circuit 13b) from the two's complement representation to the partial sign magnitude—representation,
outputs to the data line 205f the data 26a received from in2 and converted by the first conversion circuit 231 (the conversion circuit 13c) from the two's complement representation to the partial sign magnitude—representation,
outputs to the data line 205g the data 27a received from in3 and converted by the first conversion circuit 231 (the conversion circuit 13d) from the two's complement representation to the partial sign magnitude—representation,
outputs to the data line 205h the data 28a received from in4 and converted by the first conversion circuit 231 (the conversion circuit 13e) from the two's complement representation to the partial sign magnitude—representation,
outputs to the data line 205a the data 29a received from in5 and converted by the first conversion circuit 231 (the conversion circuit 13f) from the two's complement representation to the partial sign magnitude—representation,
outputs to the data line 205b the data 30a received from in6 and converted by the first conversion circuit 231 (the conversion circuit 13g) from the two's complement representation to the partial sign magnitude—representation, and
outputs to the data line 205c the data 31a received from in7 and converted by the first conversion circuit 231 (the conversion circuit 13h) from the two's complement representation to the partial sign magnitude—representation.

In the cycle t4,

the first data distribution part 202
outputs to the data line 205e the data 32a received from in0 and converted by the first conversion circuit 231 (the conversion circuit 13a) from the two's complement representation to the partial sign magnitude—representation,
outputs to the data line 205f the data 33a received from in1 and converted by the first conversion circuit 231 (the conversion circuit 13b) from the two's complement representation to the partial sign magnitude—representation,
outputs to the data line 205g the data 34a received from in2 and converted by the first conversion circuit 231 (the conversion circuit 13c) from the two's complement representation to the partial sign magnitude—representation,
outputs to the data line 205h the data 35a received from in3 and converted by the first conversion circuit 231 (the conversion circuit 13d) from the two's complement representation to the partial sign magnitude—representation,
outputs to the data line 205a the data 36a received from in4 and converted by the first conversion circuit 231 (the conversion circuit 13e) from the two's complement representation to the partial sign magnitude—representation,
outputs to the data line 205b the data 37a received from in5 and converted by the first conversion circuit 231 (the conversion circuit 13f) from the two's complement representation to the partial sign magnitude—representation,
outputs to the data line 205c the data 38a received from in6 and converted by the first conversion circuit 231 (the conversion circuit 13g) from the two's complement representation to the partial sign magnitude—representation, and
outputs to the data line 205d the data 39a received from in7 and converted by the first conversion circuit 231 (the conversion circuit 13h) from the two's complement representation to the partial sign magnitude—representation.

In the cycle t5,

the first data distribution part 202
outputs to the data line 205f the data 40a received from in0 and converted by the first conversion circuit 231 (the conversion circuit 13a) from the two's complement representation to the partial sign magnitude—representation,
outputs to the data line 205g the data 41a received from in1 and converted by the first conversion circuit 231 (the conversion circuit 13b) from the two's complement representation to the partial sign magnitude—representation,
outputs to the data line 205h the data 42a received from in2 and converted by the first conversion circuit 231 (the conversion circuit 13c) from the two's complement representation to the partial sign magnitude—representation,
outputs to the data line 205a the data 43a received from in3 and converted by the first conversion circuit 231 (the conversion circuit 13d) from the two's complement representation to the partial sign magnitude—representation,
outputs to the data line 205b the data 44a received from in4 and converted by the first conversion circuit 231 (the conversion circuit 13e) from the two's complement representation to the partial sign magnitude—representation,
outputs to the data line 205c the data 45a received from in5 and converted by the first conversion circuit 231 (the conversion circuit 13f) from the two's complement representation to the partial sign magnitude—representation,
outputs to the data line 205d the data 46a received from in6 and converted by the first conversion circuit 231 (the conversion circuit 13g) from the two's complement representation to the partial sign magnitude—representation, and
outputs to the data line 205e the data 47a received from in7 and converted by the first conversion circuit 231 (the conversion circuit 13h) from the two's complement representation to the partial sign magnitude—representation.

In the cycle t6,

the first data distribution part 202
outputs to the data line 205g the data 48a received from in0 and converted by the first conversion circuit 231 (the conversion circuit 13a) from the two's complement representation to the partial sign magnitude—representation,
outputs to the data line 205h the data 49a received from in1 and converted by the first conversion circuit 231 (the conversion circuit 13b) from the two's complement representation to the partial sign magnitude—representation,
outputs to the data line 205a the data 50a received from in2 and converted by the first conversion circuit 231 (the conversion circuit 13c) from the two's complement representation to the partial sign magnitude—representation,
outputs to the data line 205b the data 51a received from in3 and converted by the first conversion circuit 231 (the conversion circuit 13d) from the two's complement representation to the partial sign magnitude—representation,
outputs to the data line 205c the data 52a received from in4 and converted by the first conversion circuit 231 (the conversion circuit 13e) from the two's complement representation to the partial sign magnitude—representation,
outputs to the data line 205d the data 53a received from in5 and converted by the first conversion circuit 231 (the conversion circuit 13f) from the two's complement representation to the partial sign magnitude—representation,
outputs to the data line 205e the data 54a received from in6 and converted by the first conversion circuit 231 (the conversion circuit 13g) from the two's complement representation to the partial sign magnitude—representation, and
outputs to the data line 205f the data 55a received from in7 and converted by the first conversion circuit 231 (the conversion circuit 13h) from the two's complement representation to the partial sign magnitude—representation.

In the cycle t7,

the first data distribution part 202
outputs to the data line 205h the data 56a received from in0 and converted by the first conversion circuit 231 (the conversion circuit 13a) from the two's complement representation to the partial sign magnitude—representation,
outputs to the data line 205a the data 57a received from in1 and converted by the first conversion circuit 231 (the conversion circuit 13b) from the two's complement representation to the partial sign magnitude—representation,
outputs to the data line 205b the data 58a received from in2 and converted by the first conversion circuit 231 (the conversion circuit 13c) from the two's complement representation to the partial sign magnitude—representation,
outputs to the data line 205c the data 59a received from in3 and converted by the first conversion circuit 231 (the conversion circuit 13d) from the two's complement representation to the partial sign magnitude—representation,
outputs to the data line 205d the data 60a received from in4 and converted by the first conversion circuit 231 (the conversion circuit 13e) from the two's complement representation to the partial sign magnitude—representation,
outputs to the data line 205e the data 61a received from in5 and converted by the first conversion circuit 231 (the conversion circuit 13f) from the two's complement representation to the partial sign magnitude—representation,
outputs to the data line 205f the data 62a received from in6 and converted by the first conversion circuit 231 (the conversion circuit 13g) from the two's complement representation to the partial sign magnitude—representation, and
outputs to the data line 205g the data 63a received from in7 and converted by the first conversion circuit 231 (the conversion circuit 13h) from the two's complement representation to the partial sign magnitude—representation.

As described above, the first data distribution part 202 performs rotation processing on eight pieces of data simultaneously received in parallel and outputs the results. It may be easily realized by, for example, a shift circuit.

Likewise, the first data distribution part 202 performs assignment operation on:
the data 0b to 63b in the cycles t9 to t15, and
the data 0c to 63c in the cycles t16 to t23.

The next describes read and write operations of the write address control part 212, the read address control part 213, and the RAM circuits 210a to 210h controlled thereby.

The write address control part 212 and the read address control part 213 operate by referring to the operation mode 201. Here, the operation mode 201 is a control signal provided by a higher-level control circuit (not shown in the drawing) such as a CPU (Central Processing Unit) and is either a first or a second operation mode.

The operation mode 201 indicates the same operation mode for eight consecutive cycles in which data for the number of points in a 64-point FFT is supplied and indicates a different operation mode every eight cycles.

More specifically, in FIG. 20, the operation mode 201 indicates operation mode 0, which is the first operation mode, in the eight cycles t0 to t7 in which the data 0a to 63a are supplied.

The operation mode 201 indicates operation mode 1, which is the second operation mode, in the eight cycles t8 to t15 in which the data 0b to 63b are supplied. In the eight cycles t8 to t15 in the operation mode 1 (the second operation mode), data are read from the RAM circuits 210a to 210h to which data are written in the eight cycles t0 to t7 in the operation mode 0 (the first operation mode).

The operation mode 201 indicates the operation mode 0 (the first operation mode) again in the eight cycles t16 to t23 in which the data 0c to 63c are supplied. In the eight cycles t16 to t23, in which the data 0c to 63c are supplied, in the operation mode 0 (the first operation mode), data are read from the RAM circuits 210a to 210h to which data are written in the eight cycles t8 to t15 in the operation mode 1 (the second operation mode).

The operation mode 201 is a signal that alternately indicates the operation mode 0 or the operation mode 1 every eight cycles thereafter.

The write address control part 212 generates a write address according to a first address order when the operation mode 201 is the operation mode 0 (the first operation mode).

The write address control part 212 generates a write address according to a second address order when the operation mode 201 is the operation mode 1 (the second operation mode).

The first address order is an address order that always specifies a different address for each of the RAM circuits 210a to 210h. In other words, in the first operation mode, different addresses from each other are always outputted to the address lines 207a to 207h.

The second address order is an address order that always specifies the same address for each of the RAM circuits 210a to 210h. In other words, in the second operation mode, the same address is always outputted to the address lines 207a to 207h.

The read address control part 213 operates in the same manner as the write address control part 212. In other words, the read address control part 213 generates a read address (different address) for each of the RAM circuits 210a to 210h according to the first address order when the operation mode 201 is the operation mode 0 (the first operation mode). The read address control part 213 generates a read address (the same address) for each of the RAM circuits 210a to 210h according to the second address order when the operation mode 201 is the operation mode 1 (the second operation mode).

With reference to FIG. 20, the following describes a concrete example of read and write operations of the write address control part 212, the read address control part 213, and the RAM circuits 210a to 210h.

First,
in the eight cycles t0 to t7, the data 0a to 63a are written to the RAM circuits 210a to 210h.
In the eight cycles t8 to t15, the data 0a to 63a written in the RAM circuits 210a to 210h are read while the data 0b to 63b are written to the RAM circuits 210a to 210h.
In the eight cycles t16 to t23, the data 0b to 63b written in the RAM circuits 210a to 210h are read while the data 0c to 63c are written to the RAM circuits 210a to 210h. Note that, although data written in previous eight cycles before t0 to t7 are read in the eight cycles t0 to t7, this is not shown in the drawing.
As is evident from FIG. 20, read and write operations of the RAM circuits 210a to 210h are always performed on the same address in the same cycle. The RAM circuits 210a to 210h prioritize reading when both writing and reading occur at the same address simultaneously. Therefore, in the RAM circuits 210a to 210h, the data 0b to 63b are written after the data 0a to 63a have been read in each of the cycles t8 to t15.

Likewise, in each of the cycles t16 to t23, the data 0c to 63c are written after the data 0b to 63b have been read.

The next describes in detail write operations of the write address control part 212 and the RAM circuits 210a to 210h controlled thereby in the cycles t0 to t7.

With reference to FIG. 20,
in the eight cycles t0 to t7, the operation mode 201 indicates the operation mode 0 (the first operation mode), and the write address control part 212 generates write addresses according to the first address order.

The RAM circuits 210a to 210h write data outputted to 207a to 207h by the first data distribution part 202 to the write addresses generated by the write address control part 212.

More specifically,

in the cycle t0,
the RAM circuit 210a writes the data 0a to an address 0 outputted to the address line 207a by the write address control part 212,
the RAM circuit 210b writes the data 1a to an address 1 outputted to the address line 207b by the write address control part 212,
the RAM circuit 210c writes the data 2a to an address 2 outputted to the address line 207c by the write address control part 212,
the RAM circuit 210d writes the data 3a to an address 3 outputted to the address line 207d by the write address control part 212,
the RAM circuit 210e writes the data 4a to an address 4 outputted to the address line 207e by the write address control part 212,
the RAM circuit 210f writes the data 5a to an address 5 outputted to the address line 207f by the write address control part 212,
the RAM circuit 210g writes the data 6a to an address 6 outputted to the address line 207g by the write address control part 212, and
the RAM circuit 210h writes the data 7a to an address 7 outputted to the address line 207h by the write address control part 212.

In the cycle t1,
the RAM circuit 210a writes the data 15a to the address 7 outputted to the address line 207a by the write address control part 212,
the RAM circuit 210b writes the data 8a to the address 0 outputted to the address line 207b by the write address control part 212,
the RAM circuit 210c writes the data 9a to the address 1 outputted to the address line 207c by the write address control part 212,
the RAM circuit 210d writes the data 10a to the address 2 outputted to the address line 207d by the write address control part 212,
the RAM circuit 210e writes the data 11a to the address 3 outputted to the address line 207e by the write address control part 212,
the RAM circuit 210f writes the data 12a to the address 4 outputted to the address line 207f by the write address control part 212,
the RAM circuit 210g writes the data 13a to the address 5 outputted to the address line 207g by the write address control part 212, and
the RAM circuit 210h writes the data 14a to the address 6 outputted to the address line 207h by the write address control part 212.

In the cycle t2,
the RAM circuit 210a writes the data 22a to the address 6 outputted to the address line 207a by the write address control part 212,
the RAM circuit 210b writes the data 23a to the address 7 outputted to the address line 207b by the write address control part 212,
the RAM circuit 210c writes the data 16a to the address 0 outputted to the address line 207c by the write address control part 212,
the RAM circuit 210d writes the data 17a to the address 1 outputted to the address line 207d by the write address control part 212,
the RAM circuit 210e writes the data 18a to the address 2 outputted to the address line 207e by the write address control part 212,
the RAM circuit 210f writes the data 19a to the address 3 outputted to the address line 207f by the write address control part 212,
the RAM circuit 210g writes the data 20a to the address 4 outputted to the address line 207g by the write address control part 212, and
the RAM circuit 210h writes the data 21a to the address 5 outputted to the address line 207h by the write address control part 212.

In the cycle t3
the RAM circuit 210a writes the data 29a to the address outputted to the address line 207a by the write address control part 212,
the RAM circuit 210b writes the data 30a to the address 6 outputted to the address line 207b by the write address control part 212,
the RAM circuit 210c writes the data 31a to the address 7 outputted to the address line 207c by the write address control part 212,
the RAM circuit 210d writes the data 24a to the address 0 outputted to the address line 207d by the write address control part 212,
the RAM circuit 210e writes the data 25a to the address 1 outputted to the address line 207e by the write address control part 212,
the RAM circuit 210f writes the data 26a to the address 2 outputted to the address line 207f by the write address control part 212,
the RAM circuit 210g writes the data 27a to the address 3 outputted to the address line 207g by the write address control part 212, and
the RAM circuit 210h writes the data 28a to the address 4 outputted to the address line 207h by the write address control part 212.

In the cycle t4,
the RAM circuit 210a writes the data 36a to the address 4 outputted to the address line 207a by the write address control part 212,
the RAM circuit 210b writes the data 37a to the address 5 outputted to the address line 207b by the write address control part 212,
the RAM circuit 210c writes the data 38a to the address 6 outputted to the address line 207c by the write address control part 212,
the RAM circuit 210d writes the data 39a to the address 7 outputted to the address line 207d by the write address control part 212,
the RAM circuit 210e writes the data 32a to the address 0 outputted to the address line 207e by the write address control part 212,
the RAM circuit 210f writes the data 33a to the address 1 outputted to the address line 207f by the write address control part 212,
the RAM circuit 210g writes the data 34a to the address 2 outputted to the address line 207g by the write address control part 212, and
the RAM circuit 210h writes the data 35a to the address 3 outputted to the address line 207h by the write address control part 212.

In the cycle t5,
the RAM circuit 210a writes the data 43a to the address 3 outputted to the address line 207a by the write address control part 212,
the RAM circuit 210b writes the data 44a to the address 4 outputted to the address line 207b by the write address control part 212,
the RAM circuit 210c writes the data 45a to the address 5 outputted to the address line 207c by the write address control part 212,
the RAM circuit 210d writes the data 46a to the address 6 outputted to the address line 207d by the write address control part 212,
the RAM circuit 210e writes the data 47a to the address 7 outputted to the address line 207e by the write address control part 212,
the RAM circuit 210f writes the data 40a to the address 0 outputted to the address line 207f by the write address control part 212,
the RAM circuit 210g writes the data 41a to the address 1 outputted to the address line 207g by the write address control part 212, and
the RAM circuit 210h writes the data 42a to the address 2 outputted to the address line 207h by the write address control part 212.

In the cycle t6,
the RAM circuit 210a writes the data 50a to the address 2 outputted to the address line 207a by the write address control part 212,
the RAM circuit 210b writes the data 51a to the address 3 outputted to the address line 207b by the write address control part 212,
the RAM circuit 210c writes the data 52a to the address 4 outputted to the address line 207c by the write address control part 212,
the RAM circuit 210d writes the data 53a to the address 5 outputted to the address line 207d by the write address control part 212,
the RAM circuit 210e writes the data 54a to the address 6 outputted to the address line 207e by the write address control part 212,
the RAM circuit 210f writes the data 55a to the address 7 outputted to the address line 207f by the write address control part 212,
the RAM circuit 210g writes the data 48a to the address 0 outputted to the address line 207g by the write address control part 212, and
the RAM circuit 210h writes the data 49a to the address 1 outputted to the address line 207h by the write address control part 212.

In the cycle t7
the RAM circuit 210a writes the data 57a to the address 1 outputted to the address line 207a by the write address control part 212,
the RAM circuit 210b writes the data 58a to the address 2 outputted to the address line 207b by the write address control part 212,
the RAM circuit 210c writes the data 59a to the address 3 outputted to the address line 207c by the write address control part 212,
the RAM circuit 210d writes the data 60a to the address 4 outputted to the address line 207d by the write address control part 212,
the RAM circuit 210e writes the data 61a to the address 5 outputted to the address line 207e by the write address control part 212,
the RAM circuit 210f writes the data 62a to the address 6 outputted to the address line 207f by the write address control part 212,
the RAM circuit 210g writes the data 63a to the address 7 outputted to the address line 207g by the write address control part 212, and
the RAM circuit 210h writes the data 56a to the address 0 outputted to the address line 207h by the write address control part 212.

As described above, in the first address order, addresses different from each other are outputted to the address lines 207a to 207h that specify the write addresses of the RAM circuits 210a to 210h.

In each of the cycles t0 to t7, a different address is outputted to each of the address lines 207a to 207h. For instance, different addresses, the addresses 0 to 7, are outputted to the address line 207a in the cycles t0 to t7.

The next describes a concrete example of read operations of the read address control part 213 and the RAM circuits 210a to 210h controlled thereby in the cycles t8 to t15.

As a result of the write operations in the cycles t0 to t7, at the time of the cycle t8, the RAM circuits 210a to 210h store the data 0a to 63a, as shown in FIG. 16.

In the eight cycles t8 to t15, the operation mode 201 indicates the operation mode 1 (the second operation mode), and the read address control part 213 generates read addresses according to the second address order. The RAM circuits 210a to 210h output the stored data to the data lines 206a to 206h from the read addresses generated by the read address control part 213.

More specifically,
in the cycle t8,
the read address control part 213 outputs the address 0 to all the address lines 208a to 208h,
the RAM circuit 210a reads the data 0a from the address 0,
the RAM circuit 210b reads the data 8a from the address 0,
the RAM circuit 210c reads the data 16a from the address 0,
the RAM circuit 210d reads the data 24a from the address 0,
the RAM circuit 210e reads the data 32a from the address 0,
the RAM circuit 210f reads the data 40a from the address 0,
the RAM circuit 210g reads the data 48a from the address 0, and
the RAM circuit 210h reads the data 56a from the address 0.

In the cycle t9,
the read address control part 213 outputs the address 1 to all the address lines 208a to 208h,
the RAM circuit 210a reads the data 57a from the address 1,
the RAM circuit 210b reads the data 1a from the address 1,
the RAM circuit 210c reads the data 9a from the address 1,
the RAM circuit 210d reads the data 17a from the address 1,
the RAM circuit 210e reads the data 25a from the address 1,
the RAM circuit 210f reads the data 33a from the address 1,
the RAM circuit 210g reads the data 41a from the address 1, and
the RAM circuit 210h reads the data 49a from the address 1.

In the cycle t10,
the read address control part 213 outputs the address 2 to all the address lines 208a to 208h,
the RAM circuit 210a reads the data 50a from the address 2,
the RAM circuit 210b reads the data 58a from the address 2,
the RAM circuit 210c reads the data 2a from the address 2,
the RAM circuit 210d reads the data 10a from the address 2,
the RAM circuit 210e reads the data 18a from the address 2,
the RAM circuit 210f reads the data 26a from the address 2,
the RAM circuit 210g reads the data 34a from the address 2, and
the RAM circuit 210h reads the data 42a from the address 2.

In the cycle t11,
the read address control part 213 outputs the address 3 to all the address lines 208a to 208h,
the RAM circuit 210a reads the data 43a from the address 3,
the RAM circuit 210b reads the data 51a from the address 3,
the RAM circuit 210c reads the data 59a from the address 3,
the RAM circuit 210d reads the data 3a from the address 3,
the RAM circuit 210e reads the data 11a from the address 3,
the RAM circuit 210f reads the data 19a from the address 3,
the RAM circuit 210g reads the data 27a from the address 3, and
the RAM circuit 210h reads the data 35a from the address 3.

In the cycle t12,
the read address control part 213 outputs the address 4 to all the address lines 208a to 208h,
the RAM circuit 210a reads the data 36a from the address 4,
the RAM circuit 210b reads the data 44a from the address 4,
the RAM circuit 210c reads the data 52a from the address 4,
the RAM circuit 210d reads the data 60a from the address 4,
the RAM circuit 210e reads the data 4a from the address 4,
the RAM circuit 210f reads the data 12a from the address 4,
the RAM circuit 210g reads the data 20a from the address 4, and
the RAM circuit 210h reads the data 28a from the address 4.

In the cycle t13,
the read address control part 213 outputs the address 5 to all the address lines 208a to 208h,
the RAM circuit 210a reads the data 29a from the address 5,
the RAM circuit 210b reads the data 37a from the address 5,
the RAM circuit 210c reads the data 45a from the address 5,
the RAM circuit 210d reads the data 53a from the address 5,
the RAM circuit 210e reads the data 61a from the address 5,
the RAM circuit 210f reads the data 5a from the address 5,
the RAM circuit 210g reads the data 13a from the address 5, and
the RAM circuit 210h reads the data 21a from the address 5.

In the cycle t14,
the read address control part 213 outputs the address 6 to all the address lines 208a to 208h,
the RAM circuit 210a reads the data 22a from the address 6,
the RAM circuit 210b reads the data 30a from the address 6,
the RAM circuit 210c reads the data 38a from the address 6,
the RAM circuit 210d reads the data 46a from the address 6,
the RAM circuit 210e reads the data 54a from the address 6,
the RAM circuit 210f reads the data 62a from the address 6,
the RAM circuit 210g reads the data 6a from the address 6, and
the RAM circuit 210h reads the data 14a from the address 6.

In the cycle t15,
the read address control part 213 outputs the address 7 to all the address lines 208a to 208h,
the RAM circuit 210a reads the data 15a from the address 7,
the RAM circuit 210b reads the data 23a from the address 7,
the RAM circuit 210c reads the data 31a from the address 7,
the RAM circuit 210d reads the data 39a from the address 7,
the RAM circuit 210e reads the data 47a from the address 7,
the RAM circuit 210f reads the data 55a from the address 7,
the RAM circuit 210g reads the data 63a from the address 7, and
the RAM circuit 210h reads the data 7a from the address 7.

As described above, in the second address order, the same address is outputted to all the address lines 208a to 208h that specify the read addresses of the RAM circuits 210a to 210h. In each of the cycles t8 to t15, a different address is outputted to each of the address lines 208a to 208h. For instance, different addresses, the addresses 0 to 7, are outputted to the address line 208a in the cycles t8 to t15.

The next describes a concrete example of write operations of the write address control part 212 and the RAM circuits 210a to 210h controlled thereby in the cycles t8 to t15.

In the eight cycles t8 to t15, the operation mode 201 indicates the operation mode 1 (the second operation mode), and the write address control part 212 generates write addresses according to the second address order.

The RAM circuits 210a to 210h write data outputted to the data lines 205a to 205h by the first data distribution part 202 to the write addresses generated by the write address control part 212.

More specifically,
in the cycle t8,
the write address control part 212 outputs the address 0 to all the address lines 207a to 207h,
the RAM circuit 210a writes the data 0b to the address 0,
the RAM circuit 210b writes the data 1b to the address 0,
the RAM circuit 210c writes the data 2b to the address 0,
the RAM circuit 210d writes the data 3b to the address 0,
the RAM circuit 210e writes the data 4b to the address 0,
the RAM circuit 210f writes the data 5b to the address 0,
the RAM circuit 210g writes the data 6b to the address 0, and
the RAM circuit 210h writes the data 7b to the address 0.

In the cycle t9,
the write address control part 212 outputs the address 1 to all the address lines 207a to 207h,
the RAM circuit 210a writes the data 15b to the address 1,
the RAM circuit 210b writes the data 8b to the address 1,
the RAM circuit 210c writes the data 9b to the address 1,
the RAM circuit 210d writes the data 10b to the address 1,
the RAM circuit 210e writes the data 11b to the address 1,
the RAM circuit 210f writes the data 12b to the address 1,
the RAM circuit 210g writes the data 13b to the address 1, and
the RAM circuit 210h writes the data 14b to the address 1.

In the cycle t10,
the write address control part 212 outputs the address 2 to all the address lines 207a to 207h,
the RAM circuit 210a writes the data 22b to the address 2,
the RAM circuit 210b writes the data 23b to the address 2,
the RAM circuit 210c writes the data 16b to the address 2,
the RAM circuit 210d writes the data 17b to the address 2,
the RAM circuit 210e writes the data 18b to the address 2,
the RAM circuit 210f writes the data 19b to the address 2,
the RAM circuit 210g writes the data 20b to the address 2, and
the RAM circuit 210h writes the data 21b to the address 2.

In the cycle t11,
the write address control part 212 outputs the address 3 to all the address lines 207a to 207h,
the RAM circuit 210a writes the data 29b to the address 3,
the RAM circuit 210b writes the data 30b to the address 3,
the RAM circuit 210c writes the data 31b to the address 3,
the RAM circuit 210d writes the data 24b to the address 3,
the RAM circuit 210e writes the data 25b to the address 3,
the RAM circuit 210f writes the data 26b to the address 3,
the RAM circuit 210g writes the data 27b to the address 3, and
the RAM circuit 210h writes the data 28b to the address 3.

In the cycle t12,
the write address control part 212 outputs the address 4 to all the address lines 207a to 207h,
the RAM circuit 210a writes the data 36b to the address 4,
the RAM circuit 210b writes the data 37b to the address 4,
the RAM circuit 210c writes the data 38b to the address 4,
the RAM circuit 210d writes the data 39b to the address 4,
the RAM circuit 210e writes the data 32b to the address 4,
the RAM circuit 210f writes the data 33b to the address 4,
the RAM circuit 210g writes the data 34b to the address 4, and
the RAM circuit 210h writes the data 35b to the address 4.

In the cycle t13,
the write address control part 212 outputs the address 5 to all the address lines 207a to 207h,
the RAM circuit 210a writes the data 43b to the address 5,
the RAM circuit 210b writes the data 44b to the address 5,
the RAM circuit 210c writes the data 45b to the address 5,
the RAM circuit 210d writes the data 46b to the address 5,
the RAM circuit 210e writes the data 47b to the address 5,
the RAM circuit 210f writes the data 40b to the address 5,
the RAM circuit 210g writes the data 41b to the address 5, and
the RAM circuit 210h writes the data 42b to the address 5.

In the cycle t14,
the write address control part 212 outputs the address 6 to all the address lines 207a to 207h,
the RAM circuit 210a writes the data 50b to the address 6,
the RAM circuit 210b writes the data 51b to the address 6,
the RAM circuit 210c writes the data 52b to the address 6,
the RAM circuit 210d writes the data 53b to the address 6,
the RAM circuit 210e writes the data 54b to the address 6,
the RAM circuit 210f writes the data 55b to the address 6,
the RAM circuit 210g writes the data 48b to the address 6, and
the RAM circuit 210h writes the data 49b to the address 6.

In the cycle t15,
the write address control part 212 outputs the address 7 to all the address lines 207a to 207h,
the RAM circuit 210a writes the data 57b to the address 7,
the RAM circuit 210b writes the data 58b to the address 7,
the RAM circuit 210c writes the data 59b to the address 7,
the RAM circuit 210d writes the data 60b to the address 7,
the RAM circuit 210e writes the data 61b to the address 7,
the RAM circuit 210f writes the data 62b to the address 7,
the RAM circuit 210g writes the data 63b to the address 7, and
the RAM circuit 210h writes the data 56b to the address 7.

As described above, in the second address order, the same address is outputted to all the address lines 207a to 207h that specify the write addresses of the RAM circuits 210a to 210h.

In each of the cycles t8 to t15, a different address is outputted to each of the address lines 207a to 207h. For instance, different addresses, the addresses 0 to 7, are outputted to the address line 207a in the cycles t0 to t7.

The next describes a concrete example of read operations of the read address control part 213 and the RAM circuits 210a to 210h controlled thereby in the cycles t16 to t23.

As a result of the write operations in the cycles t8 to t15, at the time of the cycle t16, the RAM circuits 210a to 210h store the data 0b to 63b, as shown in FIG. 17.

In the eight cycles t16 to t23, the operation mode 201 indicates the operation mode 0 (the first operation mode), and the read address control part 213 generates read addresses according to the first address order. The RAM circuits 210a to 210h output the stored data to the data lines 206a to 206h from the read addresses generated by the read address control part 213.

More specifically, in the cycle t16,
the RAM circuit 210a reads the data 0b from the address 0 outputted to the address line 208a by the read address control part 213,
the RAM circuit 210b reads the data 8b from the address 1 outputted to the address line 208b by the read address control part 213,
the RAM circuit 210c reads the data 16b from the address 2 outputted to the address line 208c by the read address control part 213,
the RAM circuit 210d reads the data 24b from the address 3 outputted to the address line 208d by the read address control part 213,
the RAM circuit 210e reads the data 32b from the address 4 outputted to the address line 208e by the read address control part 213,
the RAM circuit 210f reads the data 40b from the address 5 outputted to the address line 208f by the read address control part 213,
the RAM circuit 210g reads the data 48b from the address 6 outputted to the address line 208g by the read address control part 213, and
the RAM circuit 210h reads the data 56b from the address 7 outputted to the address line 208h by the read address control part 213.

In the cycle t17,
the RAM circuit 210a reads the data 57b from the address 7 outputted to the address line 208a by the read address control part 213,
the RAM circuit 210b reads the data 1b from the address 0 outputted to the address line 208b by the read address control part 213,
the RAM circuit 210c reads the data 9b from the address 1 outputted to the address line 208c by the read address control part 213,
the RAM circuit 210d reads the data 17b from the address 2 outputted to the address line 208d by the read address control part 213,
the RAM circuit 210e reads the data 25b from the address 3 outputted to the address line 208e by the read address control part 213,
the RAM circuit 210f reads the data 33b from the address 4 outputted to the address line 208f by the read address control part 213,
the RAM circuit 210g reads the data 41b from the address 5 outputted to the address line 208g by the read address control part 213, and
the RAM circuit 210h reads the data 49b from the address 6 outputted to the address line 208h by the read address control part 213.

In the cycle t18,
the RAM circuit 210a reads the data 50b from the address 6 outputted to the address line 208a by the read address control part 213,
the RAM circuit 210b reads the data 58b from the address 7 outputted to the address line 208b by the read address control part 213,
the RAM circuit 210c reads the data 2b from the address 0 outputted to the address line 208c by the read address control part 213,
the RAM circuit 210d reads the data 10b from the address 1 outputted to the address line 208d by the read address control part 213,
the RAM circuit 210e reads the data 18b from the address 2 outputted to the address line 208e by the read address control part 213,
the RAM circuit 210f reads the data 26b from the address 3 outputted to the address line 208f by the read address control part 213,
the RAM circuit 210g reads the data 34b from the address 4 outputted to the address line 208g by the read address control part 213, and
the RAM circuit 210h reads the data 42b from the address 5 outputted to the address line 208h by the read address control part 213.

In the cycle t19,
the RAM circuit 210a reads the data 43b from the address 5 outputted to the address line 208a by the read address control part 213,
the RAM circuit 210b reads the data 51b from the address 6 outputted to the address line 208b by the read address control part 213,
the RAM circuit 210c reads the data 59b from the address 7 outputted to the address line 208c by the read address control part 213,
the RAM circuit 210d reads the data 3b from the address 0 outputted to the address line 208d by the read address control part 213,
the RAM circuit 210e reads the data 11b from the address 1 outputted to the address line 208e by the read address control part 213,
the RAM circuit 210f reads the data 19b from the address 2 outputted to the address line 208f by the read address control part 213,
the RAM circuit 210g reads the data 27b from the address 3 outputted to the address line 208g by the read address control part 213, and
the RAM circuit 210h reads the data 35b from the address 4 outputted to the address line 208h by the read address control part 213.

In the cycle t20,
the RAM circuit 210a reads the data 36b from the address 4 outputted to the address line 208a by the read address control part 213,
the RAM circuit 210b reads the data 44b from the address 5 outputted to the address line 208b by the read address control part 213,
the RAM circuit 210c reads the data 52b from the address 6 outputted to the address line 208c by the read address control part 213,
the RAM circuit 210d reads the data 60b from the address 7 outputted to the address line 208d by the read address control part 213,
the RAM circuit 210e reads the data 4b from the address 0 outputted to the address line 208e by the read address control part 213,
the RAM circuit 210f reads the data 12b from the address 1 outputted to the address line 208f by the read address control part 213,
the RAM circuit 210g reads the data 20b from the address 2 outputted to the address line 208g by the read address control part 213, and
the RAM circuit 210h reads the data 28b from the address 3 outputted to the address line 208h by the read address control part 213.

In the cycle t21,
the RAM circuit 210a reads the data 29b from the address 3 outputted to the address line 208a by the read address control part 213,
the RAM circuit 210b reads the data 37b from the address 4 outputted to the address line 208b by the read address control part 213,
the RAM circuit 210c reads the data 45b from the address 5 outputted to the address line 208c by the read address control part 213,
the RAM circuit 210d reads the data 53b from the address 6 outputted to the address line 208d by the read address control part 213,
the RAM circuit 210e reads the data 61b from the address 7 outputted to the address line 208e by the read address control part 213,
the RAM circuit 210f reads the data 5b from the address 0 outputted to the address line 208f by the read address control part 213,
the RAM circuit 210g reads the data 13b from the address 1 outputted to the address line 208g by the read address control part 213, and
the RAM circuit 210h reads the data 21b from the address 2 outputted to the address line 208h by the read address control part 213.

In the cycle t22,
the RAM circuit 210a reads the data 22b from the address 2 outputted to the address line 208a by the read address control part 213,
the RAM circuit 210b reads the data 30b from the address 3 outputted to the address line 208b by the read address control part 213,
the RAM circuit 210c reads the data 38b from the address 4 outputted to the address line 208c by the read address control part 213,
the RAM circuit 210d reads the data 46b from the address 5 outputted to the address line 208d by the read address control part 213,
the RAM circuit 210e reads the data 54b from the address 6 outputted to the address line 208e by the read address control part 213,
the RAM circuit 210f reads the data 62b from the address 7 outputted to the address line 208f by the read address control part 213,
the RAM circuit 210g reads the data 6b from the address 0 outputted to the address line 208g by the read address control part 213, and
the RAM circuit 210h reads the data 14b from the address 1 outputted to the address line 208h by the read address control part 213.

In the cycle t23,
the RAM circuit 210a reads the data 15b from the address 1 outputted to the address line 208a by the read address control part 213,
the RAM circuit 210b reads the data 23b from the address 2 outputted to the address line 208b by the read address control part 213,
the RAM circuit 210c reads the data 31b from the address 3 outputted to the address line 208c by the read address control part 213,
the RAM circuit 210d reads the data 39b from the address 4 outputted to the address line 208d by the read address control part 213,
the RAM circuit 210e reads the data 47b from the address 5 outputted to the address line 208e by the read address control part 213,
the RAM circuit 210f reads the data 55b from the address 6 outputted to the address line 208f by the read address control part 213,
the RAM circuit 210g reads the data 63b from the address 7 outputted to the address line 208g by the read address control part 213, and
the RAM circuit 210h reads the data 7b from the address 0 outputted to the address line 208h by the read address control part 213.

As described above, in the first address order, addresses different from each other are outputted to the address lines 208a to 208h that specify the read addresses of the RAM circuits 210a to 210h.

In each of the cycles t16 to t23, a different address is outputted to each of the address lines 208a to 208h. For instance, different addresses, the addresses 0 to 7, are outputted to the address line 208a in the cycles t16 to t23.

The next describes an operation of the second data distribution part 203 in the cycles t8 to t15.

More specifically, in the cycle t8,
the data 0a, 8a, 16a, 24a, 32a, 40a, 48a, and 56a received from the data lines 206a, 206b, 206c, 206d, 206e, 206f, 206g, and 206h are outputted from the data lines 209a, 209b, 209c, 209d, 209e, 209f, 209g, and 209h.

In the cycle t9,
the data 57a, 1a, 9a, 17a, 25a, 33a, 41a, and 49a received from the data lines 206a, 206b, 206c, 206d, 206e, 206f, 206g, and 206h are outputted from the data lines 209h, 209a, 209b, 209c, 209d, 209e, 209f, and 209g.

In the cycle t10,
the data 50a, 58a, 2a, 10a, 18a, 26a, 34a, and 42a received from the data lines 206a, 206b, 206c, 206d, 206e, 206f, 206g, and 206h are outputted from the data lines 209g, 209h, 209a, 209b, 209c, 209d, 209e, and 209f.

In the cycle t11,
the data 43a, 51a, 59a, 3a, 11a, 19a, 27a, and 35a received from the data lines 206a, 206b, 206c, 206d, 206e, 206f, 206g, and 206h are outputted from the data lines 209f, 209g, 209h, 209a, 209b, 209c, 209d, and 209e.

In the cycle t12,
the data 36a, 44a, 52a, 60a, 4a, 12a, 20a, and 28a received from the data lines 206a, 206b, 206c, 206d, 206e, 206f, 206g, and 206h are outputted from the data lines 209e, 209f, 209g, 209h, 209a, 209b, 209c, and 209d.

In the cycle t13,
the data 29a, 37a, 45a, 53a, 61a, 5a, 13a, and 21a received from the data lines 206a, 206b, 206c, 206d, 206e, 206f, 206g, and 206h are outputted from the data lines 209d, 209e, 209f, 209g, 209h, 209a, 209b, and 209c.

In the cycle t14,
the data 22a, 30a, 38a, 46a, 54a, 62a, 6a, and 14a received from the data lines 206a, 206b, 206c, 206d, 206e, 206f, 206g, and 206h are outputted from the data lines 209c, 209d, 209e, 209f, 209g, 209h, 209a, and 209b.

In the cycle t15,
the data 15a, 23a, 31a, 49a, 47a, 55a, 63a, and 7a received from the data lines 206a, 206b, 206c, 206d, 206e, 206f, 206g, and 206h are outputted from the data lines 209b, 209c, 209d, 209e, 209f, 209g, 209h, and 209a.

As described above, as a result of the data distribution processing performed by the second data distribution part 203, the data 0a to 63a are outputted to the data lines 209a to 209h in the bit-reversed order in the cycles t8 to t15.

As the first data distribution part 202, the second data distribution part 203 performs rotation processing on eight pieces of data simultaneously received in parallel and outputs the results. It may be easily realized by, for example, a shift circuit.

The second data distribution part 203 also performs the same data distribution processing on the data 0b to 63b in the cycles t16 to t23, and the data 0b to 63b are outputted to out0 to out7 in the bit-reversed order.

The normalization circuit 20a performs normalization processing on a block of the eight pieces of data 0a, 1a, 2a, 3a, 4a, 5a, 6a, and 7a outputted by the second data distribution part 203 to the data line 209a in the cycles t8 to t15, respectively, and outputs the normalized data 25a and the maximum exponent 22a to the conversion circuit 53a. The conversion circuit 53a has the decoder circuit 54 generate a selection signal based on the maximum exponent 22a, converts the D-bits normalized data 25a to the two's complement representation, and outputs a result from the output terminal out0. For instance, the normalization circuit 20a may be configured such that a memory is provided to hold data for a time period (for instance, eight cycles) during which the maximum exponent calculation circuit 30 of FIG. 5 calculates a maximum exponent for one block of data, the memory stores the data 0a, 1a, 2a, 3a, 4a, 5a, 6a, and 7a outputted by the second data distribution part 203 in the cycles t8 to t15, a maximum exponent calculation circuit (20 in FIG. 5), not shown, calculates the maximum exponent 22a, the respective normalized data 25a obtained by shifting the data 0a, 1a, 2a, 3a, 4a, 5a, 6a, and 7a using the maximum exponent 22a is outputted together with the maximum exponent 22a in the cycles t16 to t24, and a next block of the data 0b, 1b, 2b, 3b, 4b, 5b, 6b, and 7b are sequentially stored in the memory (not shown) of the normalization circuit 20a while a maximum exponent is calculated.

Likewise, the normalization circuit 20b performs normalization processing on a block of the eight pieces of data 8a, 9a, 10a, 11a, 12a, 13a, 14a, and 15a outputted by the second data distribution part 203 to the data line 209b in the cycles t8 to t15, respectively, and outputs the normalized data 25b and the maximum exponent 22b to the conversion circuit 53b. The conversion circuit 53b generates a selection signal based on the maximum exponent 22b, converts the D-bits normalized data 25b to the two's complement representation, and outputs a result from the output terminal out1. Like the normalization circuit 20a, the normalization circuit 20b may also be configured such that a memory (not shown) having a length corresponding to the number of pieces of data in a block (for instance, eight) is provided, the memory stores the data 8a to 15a outputted by the second data distribution part 203 in the cycles t8 to t15, a maximum exponent calculation circuit (20 in FIG. 5), not shown, calculates the maximum exponent 22b, the respective normalized data 25b obtained by shifting the data 8a to 15a using the maximum exponent 22b is outputted together with the conversion exponent 22b in the cycles t16 to t23, and a next block of the data 8b to 15b are stored in the memory (not shown) of the normalization circuit 20a while a maximum exponent is calculated. Respective pairs of the normalization circuits 20c to 20h and the conversion circuits 53c to 53h operate similarly.

While the data reordering processing has been described above using an example of reordering from the sequential order to the bit-reversed order, reordering from the bit-reversed order to the sequential order can also be achieved in the same manner.

As described above, the data reordering processing part 200 of the FFT apparatus 130 achieves reordering from the “sequential order” to the “bit-reversed order” and reordering from the “bit-reversed order” to the “sequential order,” data reordering processing required in a butterfly operation, by controlling read and write operations of the RAM circuits 210a to 210h using two types of address orders, namely the first and the second address orders.

For instance, data written to the RAM circuits in the first address order are read in the second address order, and data written in the second address order are read in the first address order.

As a result, even when FFT processing is performed on signals that are supplied continuously, data reordering processing can be achieved with a RAM circuit having a storage capacity equal to the number of FFT points.

Therefore, compared with double-buffering, which requires a storage capacity at least twice the number of FFT points for data reordering processing, the present disclosure reduces the storage capacity of the RAM circuit by half, thereby reducing the circuit scale and power dissipation of the RAM circuit. As a result, the circuit scale and power dissipation of the entire FFT apparatus 130 including the data reordering processing part can be reduced.

The FFT apparatus 130 of the present disclosure reorders data from the “sequential order” to the “bit-reversed order” or from the “bit-reversed order” to the “sequential order,” which is data reordering processing required in a butterfly operation, after converting the data to the partial sign magnitude--representation. Therefore, as compared with a case where reordering processing is performed while keeping data in the two's complement representation, the percentage-activity of flip-flop circuits and selector circuits constituting the RAM circuits 210a to 210h, the first data distribution part 202, and the second data distribution part 203, can be reduced.

In the present disclosure, the conversion between the two's complement representation and the partial sign magnitude--representation can be achieved only with bit inversion processing and does not require add-one processing (increment processing) which is required in the case of the sign magnitude representation. Since a bit inversion circuit can be implemented only with an XOR circuit, this can be realized with an overwhelmingly small circuit scale, as compared with other logic processing circuits and operation processing circuits. As compared with conversion between the two's complement representation and the partial sign magnitude—representation, the number of required XOR circuits is smaller. As a result, this can be implemented with a smaller circuit scale.

Therefore, according to the present disclosure, even when processing a signal with a value which frequently changes between positive and negative in the vicinity of zero, it is possible to keep the circuit operation rate in data reordering processing to a minimum. As a result, the power dissipation in the data reordering processing part can be reduced.

The butterfly operation processing part and the twiddle factor multiplication processing part perform butterfly operation processing and twiddle factor multiplication processing in the two's complement representation. Therefore, the percentage-activity related to these arithmetic processes is not reduced. The conversion between the data representation formats, however, does not increase the circuit scale unlike in the case where the sign magnitude representation is applied.

Therefore, according to the present disclosure, the power dissipation of the entire FFT apparatus can be reduced by the amount of the power dissipation reduced in data reordering processing. Since the scale of the conversion circuit is smaller, compared to the case where the sign magnitude--representation is used, more conversion processes can be performed in more optimal locations. As a result, the power dissipation of the entire FFT apparatus can be further reduced.

The several example embodiments above can be described as (but not limited to) the following Supplementary Notes (Notes).

(Note 1) A signal processing apparatus comprises an operation processing part configured to perform operation processing on data represented in a two's complement representation and a storage processing part configured to perform storage processing on data represented in a second representation format as a data representation format.

The second representation format, with respect to the data of D bits, for a non-negative value of the data is identical to the two's complement representation therefor, and
the second representation format for a negative value of the data has a representation format in which (D−N−1) bits of the data of D-bits (where D is a positive integer greater than or equal to three; N is a positive integer such that N≤D−2) represented in the two's complement representation are bit-wise inverted, wherein the (D−N−1) bits are bits between a most significant bit indicating a sign and N consecutive lower bits including a least significant bit.

The storage processing part includes a normalization circuit configured to normalize a block constituted by a plurality of pieces of data represented in the second representation format.

The normalization circuit includes:
a maximum exponent calculation circuit configured to derive a maximum exponent from a logical operation result corresponding to a bit-wise logical OR among the plurality of pieces of data in the block for (D−1) bits excluding most significant bits of the plurality of pieces of data in the block; and
a shift circuit configured to arithmetically shift the plurality of pieces of data in the block using the maximum exponent.

(Note 2) In the signal processing apparatus according to Note 1,
the maximum exponent calculation circuit includes:
a logical OR circuit;
a register; and
a detection circuit configured to detect the maximum exponent.

The logical OR circuit is configured to output a result of a bit-wise logical OR operation between (D−1) bits excluding the most significant bit of the data supplied and a register value of (D−1) bits outputted by the register.

The register is configured to:
capture in parallel the logical OR operation result of (D−1) bits outputted by the logical OR circuit in response to a clock signal; and
hold and output the logical OR operation result of (D−1) bits as the register value, and
the register is configured to supply the register value with all the (D−1) bits set to zero to the logical OR circuit when data supplied to the logical OR circuit is a first piece of data in the block.

The detection circuit is configured to:
receive the register value when a final logical OR operation result of the block from the logical OR circuit is outputted by the register as the register value; and
detect as the maximum exponent a first bit position at which the final logical OR operation result of the block transitions from zero to one, counting from the most significant bit thereof.

(Note 3) In the signal processing apparatus according to Note 1 or 2,
the register is configured to receive a block end signal,
the logical OR circuit is configured to output as the final logical OR operation result of the block a result of a logical OR operation between a last piece of data of the plurality of pieces of data in the block and the register value from the register in a cycle in which the block end signal indicates the last piece of data in the block, and
the register is configured to:
capture the final logical OR operation result of the block in response to the clock signal;
hold and output the final logical OR operation result of the block as the register value; and
reset the register value to zero after transmitting the register value to the detection circuit.

(Note 4) In the signal processing apparatus according to any one of Notes 1 to 3,
the storage processing part includes a correction circuit configured to correct the data normalized by the normalization circuit and represented in the second representation format, and
the correction circuit includes:
a decoder circuit configured to:
decode the maximum exponent calculated by the normalization circuit; and
output a selection signal; and
a selective correction circuit configured to either output a value of each of the (D−N−1) bits between the most significant bit and N consecutive lower bits including the least significant bit (where N is a positive integer such that N≤D−2) with respect to the data normalized by the normalization circuit and represented in the second representation format as it is, or output an inverted value based on the most significant bit of the data normalized by the normalization circuit and the selection signal.

(Note 5) In the signal processing apparatus according to Note 4,
the storage processing part includes:
   a first conversion circuit configured to convert the data represented in the two's complement representation to data represented in the second representation format; and
   a second conversion circuit configured to convert the data outputted by the correction circuit and represented in the second representation format to data represented in the two's complement representation.

(Note 6) In the signal processing apparatus according to any one of Notes 1 to 3,
the storage processing part includes:
a first conversion circuit configured to convert the data represented in the two's complement representation to data represented in the second representation format; and
a second conversion circuit configured to convert data outputted by the normalization circuit and represented in the second representation format to data represented in the two's complement representation.

The second conversion circuit includes:
a decoder circuit configured to:
   decode the maximum exponent calculated by the normalization circuit; and
output a selection signal; and
a selective correction circuit configured to either output a value of each of the (D−N−1) bits between the most significant bit and N consecutive lower bits including the least significant bit (where N is a positive integer such that N≤D−2) with respect to data normalized by the normalization circuit and represented in the second representation format as it is, or output an inverted value based on the most significant bit of the data normalized by the normalization circuit and the selection signal.

(Note 7) The signal processing apparatus according to Note 6 comprises
a data reordering processing part configured to rearrange an order of a plurality of pieces of data supplied in a first order to a second order.

The data reordering processing part includes:
a first conversion circuit configured to:
receive a plurality of pieces of data represented in the two's complement representation; and
convert the received plurality of pieces of data represented in the two's complement representation to a plurality of pieces of data represented in the second representation format for output;
a first data distribution part configured to:
receive the plurality of pieces of data represented in the second representation format outputted from the first conversion circuit; and
perform data distribution processing of the received plurality of pieces of data;
a storage circuit that includes a plurality of storage elements configured to store the plurality of pieces of data, for each of a plurality of cycles;
a first control part configured to write the plurality of pieces of data represented in the second representation format to the storage circuit in accordance with one of a first address order and a second address order; and
a second control part configured to read from the storage circuit, the plurality of pieces of data, represented in the second representation format, that have been written to the storage circuit in accordance with the one of the first address order and the second address order, in accordance with other of the first address order and the second address order.

The plurality of pieces of data represented in the second representation format distributed by the first data distribution part are written to the plurality of storage elements of the storage circuit using addresses outputted from the first control part.

The data reordering processing part further includes:
a second data distribution part configured to:
receive the plurality of pieces of data represented in the second representation format read from the plurality of storage elements of the storage circuit using addresses outputted from the second control circuit; and
perform data distribution processing of the received plurality of pieces of data;
a plurality of the normalization circuits configured to receive the plurality of pieces of data represented in the second representation format outputted from the second data distribution part; and
a plurality of the second conversion circuits configured to:
receive the plurality of pieces of data, represented in the second representation format, normalized, and outputted by the plurality of the normalization circuits, and the maximum exponent;
correct a bit selected based on the maximum exponent for the (D−N−1) bits between the most significant bit and N consecutive lower bits including the least significant bit (where N is a positive integer such that N≤D−2) of the received plurality of pieces of data represented in the second representation format; and
convert the plurality of pieces of data represented in the second representation format to a plurality of pieces of data in the two's complement representation for output.

(Note 8) In the signal processing apparatus according to Note 7,
in the storage processing part,
a plurality of addresses simultaneously supplied to the plurality of storage elements are different from each other in the first address order, and
a plurality of addresses simultaneously supplied to the plurality of storage elements are identical to each other in the second address order.

(Note 9) The signal processing apparatus according to Note 7 is a signal processing apparatus that performs (n×n)-point fast Fourier transform or inverse fast Fourier transform, and the storage processing part includes first to third data reordering processing parts constituted by the data reordering processing parts.

The operation processing part includes:
first and second butterfly operation processing parts; and
a twiddle factor multiplication processing part that multiplies data by a twiddle factor.

The first data reordering processing part is configured to:
receive n pieces of data supplied in parallel in a sequential order, for n cycles;
rearrange an order of the n pieces of data to a bit-reversed order; and
output in parallel the n pieces of data rearranged to the bit-reversed order, for n cycles, the first butterfly operation processing part is configured to:
perform a butterfly operation on the n pieces of data outputted in parallel by the first data reordering processing part; and
output in parallel n pieces of data subjected to the butterfly operation,
the second data reordering processing part is configured to:
receive the n pieces of data outputted in parallel in a sequential order by the first butterfly operation processing part for n cycles;
rearrange an order of the n pieces of data to the bit-reversed order; and
output in parallel the n pieces of data rearranged to the bit-reversed order for n cycles,
the twiddle factor multiplication processing part is configured to
multiply the data outputted by the second data reordering processing part by corresponding twiddle factors,
the second butterfly operation processing part is configured to:
   perform a butterfly operation on the n pieces of data outputted by the twiddle factor multiplication processing part; and
output in parallel the n pieces of data subjected to the butterfly operation,
the third data reordering processing part is configured to:
receive the n pieces of data outputted in parallel in the bit-reversed order by the second butterfly operation processing part for the n cycles;
rearrange an order of the n pieces of data to the sequential order; and
output in parallel the n pieces of data rearranged to the sequential order, for n cycles, and
the first and the second butterfly operation processing parts and the twiddle factor multiplication processing part perform operation processing on the n pieces of data, each represented in the two's complement representation.

(Note 10) A signal processing method, comprising:
performing operation processing on data represented in a two's complement representation; and
performing storage processing on data represented in a second representation format as a data representation format,
wherein the second representation format for a non-negative data value is identical to the two's complement representation therefor,
the second representation format for a negative data value has a representation format in which (D−N−1) bits of the data of D-bits (where D is a positive integer greater than or equal to three; N is a positive integer such that N≤D−2) represented in the two's complement representation are bit-wise inverted, wherein the (D−N−1) bits are bits between a most significant bit indicating a sign and N consecutive lower bits including a least significant bit,
wherein the storage processing includes
normalization processing that, for a block constituted by a plurality of pieces of data represented in the second representation format and with respect to (D−1) lower bits excluding most significant bits of the plurality of pieces of data, derives a maximum exponent from an operation result corresponding to a bit-wise logical OR among the plurality of pieces of data and normalizes the plurality of pieces of data in the block using the maximum exponent, and
wherein the normalization processing derives a maximum exponent from a bit-wise logical operation result among the plurality of pieces of data for (D−1) lower bits excluding most significant bits of the plurality of pieces of data in the block and shifts the bit strings excluding the most significant bits of the plurality of pieces of data using the maximum exponent.

(Note 11) The signal processing method according to Note 10, wherein
in the maximum exponent deriving processing,
a logical OR circuit outputs a result of a bit-wise logical OR operation between (D−1) bits excluding the most significant bit of the data supplied and a register value of (D−1) bits outputted by the register,
the register captures in parallel the logical OR operation result of (D−1) bits outputted by the logical OR circuit in response to a clock signal and hold and outputs the logical OR operation result of (D−1) bits as the register value,
the register supplies the register value with all the (D−1) bits set to zero to the logical OR circuit when data supplied to the logical OR circuit is a first piece of data in the block, and
when a final logical OR operation result of the block from the logical OR circuit is outputted by the register as the register value,
a first bit position at which the final logical OR operation result of the block transitions from zero to one, counting from the most significant bit thereof, is detected as the maximum exponent.

(Note 12) The signal processing method according to Note 11,
wherein the register receives a block end signal,
wherein the logical OR circuit outputs as the final logical OR operation result of the block a result of a logical OR operation between a last piece of data of the plurality of pieces of data in the block and the register value from the register in a cycle in which the block end signal indicates the last piece of data in the block, and
wherein the register captures the final logical OR operation result of the block in response to the clock signal, hold and outputs the final logical OR operation result of the block as the register value, and resets the register value to zero after transmitting the register value to the detection circuit.

(Note 13) The signal processing method according to any one of Notes 10 to 12, wherein the storage processing includes correction processing correcting the data normalized by the normalization processing and represented in the second representation format, wherein the correction processing includes:
decoding the maximum exponent,
generating (D−N−1) selection signals; and
outputting either a value as it is or an inverted value for each of the (D−N−1) bits between the most significant bit and N consecutive lower bits including the least significant bit (where N is a positive integer such that N≤D−2) with respect to the normalized data represented in the second representation format based on the most significant bit of the data normalized by the normalization circuit and each of the (D−N−1) selection signals

(Note 14) The signal processing method according to Note 13, wherein the storage processing includes:
first conversion processing converting data represented in the two's complement representation from first operation processing to data represented in the second representation format; and
second conversion processing converting the data represented in the second representation format to data represented in the two's complement representation and outputs a result to second operation processing.

(Note 15) The signal processing method according to any one of Notes 10 to 13, wherein the storage processing includes:
first conversion processing converting the data represented in the two's complement representation from the first operation processing to data represented in the second representation format, and
when converting the data represented in the second representation format to data represented in the two's complement representation and outputting a result to second operation processing
the second conversion processing including:
decoding the maximum exponent, outputs (D−N−1) selection signals; and
outputting either a value as it is or an inverted value for each of the (D−N−1) bits between the most significant bit and N consecutive lower bits including the least significant bit (where N is a positive integer such that N≤D−2) with respect to the normalized data represented in the second representation format based on the most significant bit of the data normalized by the normalization circuit and each of the (D−N−1) selection signals

(Note 16) The signal processing method according to Note 14,
wherein the storage processing includes data reordering processing that rearranges an order of a plurality of pieces of data supplied in a first order to a second order.

The data reordering processing includes:
first conversion processing that receives the plurality of pieces of data represented in the two's complement representation and converts the received plurality of pieces of data represented in the two's complement representation to a plurality of pieces of data represented in the second representation format for output;
first data distribution processing that receives the plurality of pieces of data represented in the second representation format outputted from the first conversion circuit and performs data distribution processing of the received plurality of pieces of data;
processing that writes the plurality of pieces of data represented in the second representation format to a storage circuit, including a plurality of storage elements configured to store the plurality of pieces of data for each of a plurality of cycles, in accordance with one of a first address order and a second address order; and
processing that reads from the storage circuit, the plurality of pieces of data, represented in the second representation format, that have been written to the storage circuit in accordance with the one of the first address order and the second address order, in accordance with other of the first address order and the second address order.

The plurality of pieces of data represented in the second representation format distributed by the first data distribution processing are written to the plurality of storage elements of the storage circuit.

The data reordering processing further includes:
second data distribution processing that receives the plurality of pieces of data represented in the second representation format read from the plurality of storage elements of the storage circuit and performs data distribution processing of the received plurality of pieces of data; and
   a plurality of the normalization processings that receive the plurality of pieces of data represented in the second representation format outputted by the second data distribution processing,
wherein a plurality of the second conversion processings receive the plurality of pieces of data, represented in the second representation format and normalize d by the plurality of the normalization processings, and the maximum exponent, correct a bit selected based on the maximum exponent for the (D−N−1) bits between the most significant bit and N consecutive lower bits including the least significant bit (where N is a positive integer such that N≤D−2) of the received plurality of pieces of data represented in the second representation format, and convert the plurality of pieces of data represented in the second representation format to a plurality of pieces of data in the two's complement representation for output.
[Reference Literature 1] Japanese Patent Kokai Publication No. JP-H08-137832A
[Reference Literature 2] Japanese Patent Kokai Publication No. JP-P2001-56806A
[Reference Literature 3] Japanese Patent No. 4883251
[Reference Literature 4]J. W. Cooley, J. W. Tukey, “An Algorithm for the Machine Calculation of Complex Fourier Series,” Mathematics of Computation, US, American Mathematical Society, April 1965, Vol. 19, No. 90, pp. 297-301
[Reference Literature 5]D. P. Kolba, “A Prime Factor FFT Algorithm Using High-Speed Convolution,” IEEE Trans. on Acoustics, US, IEEE Signal Processing Society, August 1977, Vol. 29, No. 4, pp. 281-294

Each disclosure of Patent Literature 1 and Reference Literatures 1 to 5 cited above is incorporated herein in its entirety by reference thereto. It is to be noted that it is possible to modify or adjust the example embodiments or examples within the scope of the entirety of the present disclosure (including the Claims) and based on the basic technical concept thereof. Further, it is possible to variously combine or select a wide variety of the disclosed elements (including the individual elements of the individual claims, the individual elements of the individual examples, and the individual elements of the individual figures) within the scope of the Claims. That is, it is self-explanatory that the present disclosure includes any types of variations and modifications to be done by a person skilled in the art according to the whole disclosure, and the technical concept of the present disclosure.

What is claimed is:

1. A signal processing apparatus comprising:
an operation processing part configured to perform operation processing on data represented in a two's complement representation; and
a storage processing part configured to perform storage processing on data represented in a second representation format as a data representation format,
wherein the second representation format, while for the data of D-bits of a non-negative value being identical to the two's complement representation, for the data of D-bits of a negative value has a representation format in which (D−N−1) bits of the data of D-bits (where D is a positive integer greater than or equal to three; N is a positive integer such that N≤D−2) represented in the two's complement representation are bit-wise inverted, wherein the (D−N−1) bits are bits between a most significant bit indicating a sign and N consecutive lower bits including a least significant bit, and
wherein the storage processing part includes
a normalization circuit configured to normalize a block constituted by a plurality of pieces of data, each represented in the second representation format, wherein the normalization circuit includes:
a maximum exponent calculation circuit configured to derive a maximum exponent from a logical operation result corresponding to a bit-wise logical OR among the plurality of pieces of data in the block for (D−1) bits excluding most significant bits of the plurality of pieces of data in the block; and
a shift circuit configured to perform arithmetically shift operation of the plurality of pieces of data in the block using the maximum exponent.

2. The signal processing apparatus according to claim 1, wherein the maximum exponent calculation circuit includes:
a logical OR circuit;
a register; and
a detection circuit configured to detect the maximum exponent,
wherein the logical OR circuit is configured to output a result of a bit-wise logical OR operation between (D−1) bits excluding the most significant bit of the D-bits data received and a register value of (D−1) bits outputted by the register,
wherein the register is configured to:
capture the logical OR operation result of (D−1) bits outputted by the logical OR circuit in response to a clock signal; and
hold and output the logical OR operation result of (D−1) bits as the register value, wherein the register is configured to supply the register value with all the (D−1) bits set to zero to the logical OR circuit when data supplied to the logical OR circuit is a first piece of data in the block, and
wherein the detection circuit is configured to:
receive the register value when a final logical OR operation result for the block from the logical OR circuit is outputted by the register as the register value; and
detect, from the final logical OR operation result for the block, a first bit position counted from the most significant bit at which the final logical OR operation result for the block, transitions from zero to one, as the maximum exponent.

3. The signal processing apparatus according to claim 2, wherein the register is configured to receive a block end signal,
wherein the logical OR circuit is configured to output, as the final logical OR operation result of the block, a result of a logical OR operation between a last piece of data of the plurality of pieces of data in the block and the register value from the register in a cycle in which the block end signal indicates the last piece of data in the block, and
wherein the register is configured to:
capture the final logical OR operation result of the block in response to the clock signal;
hold and output the final logical OR operation result of the block as the register value; and
reset the register value to zero after transmitting the register value to the detection circuit.

4. The signal processing apparatus according to claim 1, wherein the storage processing part includes a correction circuit configured to correct the data normalized by the normalization circuit and represented in the second representation format, and
wherein the correction circuit includes:
a decoder circuit configured to:
decode the maximum exponent calculated by the normalization circuit, and
generate (D−N−1) selection signals for output; and
(D−N−1) selective correction circuits, each configured to:
receive each of the (D−N−1) bits between the most significant bit and N consecutive lower bits including the least significant bit (where N is a positive integer such that N≤D−2) of the D-bits data normalized by the normalization circuit and represented in the second representation format and the selection signal; the selection signal; and the most significant bit of the D-bits data normalized by the normalization circuit and represented in the second representation format and each of the (D−N−1) selection signals; and
output either a value as it is or an inverted value of each of the (D−N−1) bits received, based on the most significant bit of the D-bits data normalized by the normalization circuit and each of the (D−N−1) selection signals.

5. The signal processing apparatus according to claim 4, wherein the storage processing part includes:
a first conversion circuit configured to convert the data represented in the two's complement representation to data represented in the second representation format; and
a second conversion circuit configured to convert the data outputted by the correction circuit and represented in the second representation format to data represented in the two's complement representation.

6. The signal processing apparatus according to claim 1, wherein the storage processing part includes:
a first conversion circuit configured to convert the data represented in the two's complement representation to data represented in the second representation format; and
a second conversion circuit configured to convert data outputted by the normalization circuit and represented in the second representation format to data represented in the two's complement representation, and
wherein the second conversion circuit includes:
a decoder circuit configured to:
decode the maximum exponent calculated by the normalization circuit, and
generate (D−N−1) selection signals for output; and
(D−N−1) selective correction circuits, each configured to:
receive each of the (D−N−1) bits between the most significant bit and N consecutive lower bits including the least significant bit (where N is a positive integer such that N≤D−2) of the D-bits data normalized by the normalization circuit and represented in the second representation format and the selection signal;
the selection signal;
the most significant bit of the D-bits data normalized by the normalization circuit and represented in the second representation format; and
each of the (D−N−1) selection signals; and
output either a value as it is or an inverted value of each of the (D−N−1) bits received, based on the most significant bit of the D-bits data normalized by the normalization circuit and each of the (D−N−1) selection signals.

7. The signal processing apparatus according to claim 6, wherein the storage processing part includes
a data reordering processing part configured to rearrange an order of a plurality of pieces of data supplied in a first order to a second order,
wherein the data reordering processing part includes:
a first conversion circuit configured to:
receive a plurality of pieces of data represented in the two's complement representation; and
convert the received plurality of pieces of data represented in the two's complement representation to a plurality of pieces of data represented in the second representation format for output;
a first data distribution part configured to:
receive the plurality of pieces of data represented in the second representation format outputted from the first conversion circuit; and
perform data distribution processing of the received plurality of pieces of data;
a storage circuit that includes a plurality of storage elements configured to store the plurality of pieces of data distributed by the first data distribution part, for each of a plurality of cycles;
a first control part configured to write the plurality of pieces of data represented in the second representation format to the storage circuit in accordance with one of a first address order and a second address order; and
a second control part configured to read from the storage circuit, the plurality of pieces of data, represented in the second representation format, that have been written to the storage circuit in accordance with the one of the first address order and the second address order, in accordance with other of the first address order and the second address order,
wherein the plurality of pieces of data represented in the second representation format distributed by the first data distribution part are written to the plurality of storage elements of the storage circuit using addresses outputted from the first control part, and
wherein the data reordering processing part further includes:
a second data distribution part configured to:
receive the plurality of pieces of data represented in the second representation format read from the plurality of storage elements of the storage circuit using addresses outputted from the second control circuit; and
perform data distribution processing of the received plurality of pieces of data;
a plurality of the normalization circuits configured to receive the plurality of pieces of data represented in the second representation format outputted from the second data distribution part; and
a plurality of the second conversion circuits configured to:
receive the plurality of pieces of data, represented in the second representation format, normalized and outputted by the plurality of the normalization circuits, and the maximum exponent;
correct a bit selected based on the maximum exponent for the (D−N−1) bits between the most significant bit and N consecutive lower bits including the least significant bit (where N is a positive integer such that N≤D−2) of the received plurality of pieces of data represented in the second representation format; and
convert the normalized plurality of pieces of data represented in the second representation format to a plurality of pieces of data in the two's complement representation for output.

8. The signal processing apparatus according to claim 7, wherein in the storage processing part,
a plurality of addresses simultaneously supplied to the plurality of storage elements of the storage circuit are different from each other in the first address order, and
a plurality of addresses simultaneously supplied to the plurality of storage elements of the storage circuit are identical to each other in the second address order.

9. The signal processing apparatus according to claim 7, performing (n×n)-point fast Fourier transform or inverse fast Fourier transform, wherein the storage processing part includes
first to third data reordering processing parts, each constituted by the data reordering processing part,
wherein the operation processing part includes:
first and second butterfly operation processing parts; and
a twiddle factor multiplication processing part configured to multiply data by a twiddle factor,
wherein the first data reordering processing part is configured to:
receive n pieces of data supplied in parallel in a sequential order, for n cycles;
rearrange an order of the n pieces of data to a bit-reversed order; and
output in parallel the n pieces of data rearranged to the bit-reversed order, for n cycles,
wherein the first butterfly operation processing part is configured to:
perform a butterfly operation on the n pieces of data outputted in parallel by the first data reordering processing part; and
output in parallel n pieces of data subjected to the butterfly operation,
wherein the second data reordering processing part is configured to:
receive the n pieces of data outputted in parallel in a sequential order by the first butterfly operation processing part for n cycles;
rearrange an order of the n pieces of data to the bit-reversed order; and
output in parallel the n pieces of data rearranged to the bit-reversed order for n cycles,
wherein the twiddle factor multiplication processing part is configured to
multiply the n pieces of data outputted by the second data reordering processing part by corresponding twiddle factors,
wherein the second butterfly operation processing part is configured to:
perform a butterfly operation on the n pieces of data outputted by the twiddle factor multiplication processing part; and
output in parallel the n pieces of data subjected to the butterfly operation,
wherein the third data reordering processing part is configured to:
receive the n pieces of data outputted in parallel in the bit-reversed order by the second butterfly operation processing part for the n cycles;
rearrange an order of the n pieces of data to the sequential order; and
output in parallel the n pieces of data rearranged to the sequential order, for n cycles, and
wherein the first and the second butterfly operation processing parts and the twiddle factor multiplication processing part perform operation processing on the n pieces of data, each represented in the two's complement representation.

10. A signal processing method comprising:
performing operation processing on data represented in a two's complement representation; and
performing storage processing on data represented in a second representation format as a data representation format,
the second representation format, while for the data of D-bits of a non-negative value being identical to the two's complement representation, for the data of D-bits of a negative value, having a representation format in which (D−N−1) bits of the data of D-bits (where D is a positive integer greater than or equal to three; N is a positive integer such that N≤D−2) represented in the two's complement representation are bit-wise inverted, wherein the (D−N−1) bits are bits between a most significant bit indicating a sign and N consecutive lower bits including a least significant bit,
wherein the storage processing includes
normalization processing including;
for a block constituted by a plurality of pieces of data represented in the second representation format and with respect to bit strings of (D−1) bits excluding most significant bits of the plurality of pieces of D-bits data, deriving a maximum exponent from an operation result corresponding to a bit-wise logical OR among the plurality of pieces of D-bits data; and
shifting the bit strings excluding the most significant bits of the plurality of pieces of data using the maximum exponent.

11. The signal processing method according to claim 10, wherein the storage processing includes
correction processing correcting the data normalized by the normalization processing and represented in the second representation format, wherein the correction processing includes:
decoding the maximum exponent,
generating (D−N−1) selection signals; and
outputting either a value as it is or an inverted value for each of the (D−N−1) bits between the most significant bit and N consecutive lower bits including the least significant bit (where N is a positive integer such that N≤D−2) with respect to the normalized data represented in the second representation format based on the most significant bit of the data normalized by the normalization circuit and each of the (D−N−1) selection signals.

12. The signal processing method according to claim 10, wherein the storage processing includes:
first conversion processing converting data represented in the two's complement representation from first operation processing to data represented in the second representation format; and
second conversion processing converting the data represented in the second representation format to data represented in the two's complement representation and outputs a result to second operation processing.

13. The signal processing method according to claim 12, wherein the storage processing includes data reordering processing that rearranges an order of a plurality of pieces of data supplied in a first order to a second order,
wherein the data reordering processing includes:
the first conversion processing converting the plurality of pieces of data represented in the two's complement representation received to a plurality of pieces of data represented in the second representation format for output;
first data distribution processing performing first data distribution processing of the plurality of pieces of data outputted from the first conversion processing;
writing the plurality of pieces of data represented in the second representation format, distributed by the first data distribution processing to the plurality of storage elements of a storage circuit, for each of a plurality of cycles, in accordance with one of a first address order and a second address order; and
reading from the storage circuit, the plurality of pieces of data, represented in the second representation format that have been written to the storage circuit in accordance with the one of the first address order and the second address order, in accordance with other of the first address order and the second address order,
performing second data distribution processing performing second data distribution processing of the plurality of pieces of data read from the storage circuit;
performing normalization processing normalizing a block constituted by a plurality of pieces of data, represented in the second representation format, and outputted by the second data distribution processing; and
the second conversion processing including
correcting a bit selected for the (D−N−1) bits, based on a maximum exponent obtained by the normalization processing, the (D−N−1) bits located between the most significant bit and N consecutive lower bits including the least significant bit (where N is a positive integer such that N≤D−2) of the each of the received plurality of pieces of data represented in the second representation format, for converting the plurality of pieces of data represented in the second representation format to a plurality of pieces of data in the two's complement representation for output.
